(19) United States
(12) Patent Application Publication
(10) Pub. No.: US 2012/0181538 A1
(43) Pub. Date: Jul. 19, 2012

(54) SEMICONDUCTOR DEVICE AND METHOD FOR MANUFACTURING SEMICONDUCTOR DEVICE

(75) Inventors: Masakazu Kamura, Osaka (JP); Shigeru Aomori, Osaka (JP); Yasutaka Kuzumoto, Osaka (JP)

(73) Assignee: Sharp Kabushiki Kaisha, Osaka (JP)

(21) Appl. No.: 13/497,240

(22) PCT Filed: Oct. 19, 2010
(86) PCT No.: PCT/JP2010/068395

§ 371 Date: Mar. 20, 2012

(30) Foreign Application Priority Data
Nov. 2, 2009 (JP) 2009-252432

(51) Int. Cl. H01L 29/786; H01L 21/20

(52) U.S. Cl. 257/57; 438/483; 257/E29.273; 257/E21.09

(57) ABSTRACT

A semiconductor device (1a) which is constituted by organic semiconductors with excellent transistor characteristics and includes: a p-type organic transistor (P1) having a gate electrode (12), a source electrode (14), a drain electrode (15), and a p-type organic semiconductor layer (16); an n-type organic transistor (N1) electrically connected with the p-type organic transistor (P1) and having a gate electrode (22), a source electrode (24), a drain electrode (25), and an n-type organic semiconductor layer (26); first layers for enhancing electric charge transfer, one of the first layers being provided between the source electrode (14) and the organic semiconductor layer (16), the other of the first layers being provided between the drain electrode (25) and the organic semiconductor (26); and second layers for enhancing electric charge transfer and made from a different material from that of the first layers, one of the second layers being provided between the drain electrode (15) and the organic semiconductor layer (16), the other of the second layers being provided between the source electrode (24) and the organic semiconductor layer (26), all of the source electrodes and the drain electrodes being made from a same electrode material.

### TECHNICAL FIELD

The present invention relates to a semiconductor device and a method for fabricating the semiconductor device. Specifically, the present invention relates to (i) a semiconductor device employing a plurality of field-effect transistors each having a semiconductor layer made from organic molecules and (ii) a method for fabricating the semiconductor device.

### BACKGROUND ART

In recent years, an organic transistor, in which an organic semiconductor material is used as an active layer, has been much attracting attention. In the organic transistor, it is possible to fabricate a device without carrying out a vacuum process and a high-temperature process at 200° C. or above, unlike in a transistor using an inorganic semiconductor such as silicon. It is also possible in the organic transistor to fabricate a device by (i) a printing technique such as an ink-jet method and a screen printing method and (ii) a solution process such as a spin coat method and a casting method. This allows a device to be fabricated on a large-area substrate and a plastic substrate in the organic transistor. Such being the case, the organic transistor is expected to be applied to, for example, (i) a logic circuit such as an inverter employing a plurality of organic transistors and (ii) a flexible display and an electronic tag each employing such a logic circuit.

However, the organic transistor is inferior yet to an inorganic semiconductor device in terms of electric properties such as (i) a carrier mobility of an organic semiconductor material and (ii) a contact resistance between an organic semiconductor and a source electrode and between the organic semiconductor and a drain electrode. There is demand for improvement in such electric properties.

In this respect, a reduction in contact resistance in an interface between the organic semiconductor and the source electrode and in an interface between the organic semiconductor and the drain electrode particularly brings about an improvement in transistor characteristics, such as an improvement in mobility in the device as a whole, an improvement in an ON-state electric current, and a decrease in a threshold voltage. That is, since the organic semiconductor does not have a carrier in the semiconductor material, injection and control of a carrier by means of doping is difficult, unlike in the inorganic semiconductor organic transistor. As such, supply of the carrier in the organic transistor is carried out by injection of the carrier from the source electrode to the organic semiconductor. The contact resistance in the interface between the source electrode and the organic semiconductor layer therefore has a serious impact on the transistor characteristics.

For the same reason, the carrier injected into the organic semiconductor layer needs to be efficiently extracted from the drain electrode. This is why the reduction in contact resistance in the interface between the drain electrode and the organic semiconductor layer is an equally major problem to be solved.

FIG. 13 is a view illustrating a schematic configuration of a conventional organic transistor and resistances in the organic transistor. In a conventional organic transistor 100, a gate electrode 112 is provided on a substrate 111, a gate insulating film 113 is provided so as to cover the gate electrode 112, and a source electrode 114, a drain electrode 115 and an organic semiconductor layer 110 are provided on the gate insulating film 113 as illustrated in FIG. 13. Resistances generated in the organic transistor 100 include a contact resistance R1 in an interface between the source electrode 114 and the organic semiconductor layer 110, a resistance R2 of the organic semiconductor layer 110 itself, and a contact resistance R3 in an interface between the drain electrode 115 and the organic semiconductor layer 110.

A cause for the generation of the contact resistances R1 and R3 is an injection barrier caused by an energy gap between (i) a work function of a metal used as a material of the source electrode 114 and the drain electrode 115 and (ii) a Highest Occupied Molecular Orbital (HOMO) or a Lowest Unoccupied Molecular Orbital (LUMO) of the organic material of the organic semiconductor layer 110. The same is true of a case where (i) a source electrode and a drain electrode that are suitable for a p-type organic semiconductor layer and (ii) a source electrode and a drain electrode that are suitable for an n-type organic semiconductor layer are respectively selected. Another cause is a problem resulting from a physically poor adhesiveness due to a low affinity between different types of materials such as a metal and an organic material.

FIG. 14 is a view for illustrating how a carrier is transferred in the conventional organic transistor. FIG. 14 shows only the source electrode 114, the drain electrode 115, and a p-type organic semiconductor layer 116 in a p-type organic transistor. A hole h⁺ serves as the carrier in the p-type organic transistor. In this case, the more energy gap between (i) a work function of the source electrode 114 and the drain electrode 115 and (ii) a HOMO of the p-type organic semiconductor layer 116, for example, the higher contact resistance in an interface 117 between (i) each of the source electrode 114 and the drain electrode 115 and (ii) the p-type organic semiconductor layer 116. In a case where a physical adhesiveness between the source electrode 114 and the p-type organic semiconductor layer 116 and a physical adhesiveness between the drain electrode 115 and the p-type organic semiconductor layer 116 are weak, the contact resistances increase.

As a technique for addressing such problems, Patent Literature 1, for example, discloses an organic semiconductor device in which an electric charge injection acceleration layer, which is an organic thin film having an electric dipole moment, is provided between a source electrode and an organic semiconductor layer or between a drain electrode and the organic semiconductor layer. This allows injection of an electric charge into the organic semiconductor layer to be facilitated and an electric charge transfer characteristic to be accordingly improved.

As described above, the logic circuit or the like employing the plurality of organic transistors is expected to be applied to the flexible display, the electronic tag, and the like. However, fabrication of the logic circuit by use of an organic transistor has such problems as a complexity in the fabrication process and a high fabrication cost due to having more steps in film formation and patterning as compared with fabrication of a device employing an inorganic semiconductor.

This is caused by a necessity to use different source electrodes in the p-type organic transistor and the n-type organic transistor and different drain electrodes in the p-type organic transistor and the n-type organic transistor. This is because the barrier between (i) a work function of the source electrode and the drain electrode and (ii) a HOMO of the organic semiconductor layer needs to be small in a case where the organic semiconductor is a p-type, whereas the barrier between (iii) a work function of the source electrode and the drain electrode and (iv) a LUMO of the organic semiconductor layer needs to be small in a case where the organic semiconductor is an n-type.

Such being the case, initially, as illustrated in FIG. 12, the source electrode 114 and the drain electrode 115 for the p-type organic transistor are formed and patterned by use of an electrode material having a work function with a small barrier between the work function and the HOMO of the p-type organic semiconductor layer (see (a) of FIG. 12). After the source electrode 114 and the drain electrode 115 for the p-type organic transistor are formed, the source electrode 124 and the drain electrode 125 for the n-type organic transistor need to be formed and patterned by use of an electrode material having a work function with a small barrier between the work function and the LUMO of the n-type organic semiconductor layer (see (b) of FIG. 12).

As a technique for addressing the problem of the increased number of steps in the film formation and the patterning in the fabrication of the logic circuit by use of the plurality of organic transistors, Patent Literature 2 discloses a complementary logic circuit substrate constituted by a top gate organic thin-film transistor and a bottom gate organic thin-film transistor, which are coupled with each other. In the fabrication of the complementary logic circuit substrate, the source electrode and the drain electrode of the top gate organic thin-film transistor are formed at the same time as the gate electrode of the bottom gate organic thin-film transistor, so that the number of steps in the fabrication process is reduced as compared with conventional fabrication methods.

### CITATION LIST

### Patent Literature

Patent Literature 1
Japanese Patent Application Publication, Tokukai, No. 2005-150641 A (Publication Date: Jun. 9, 2005)

Patent Literature 2
Japanese Patent Application Publication, Tokukai, No. 2005-294785 A (Publication Date: Oct. 20, 2005)

### Nonpatent Literature

Nonpatent Literature 1
Peter V. Necliudov et al, Solid-State Electronics, 2003, 47, 259-262.

### SUMMARY OF INVENTION

### Technical Problem

However, in the conventional complementary logic circuit substrate, in a case where, for the purpose of reducing costs, the source electrode and the drain electrode of the p-type organic transistor are formed using the same electrode material as that for the source electrode and the drain electrode of the n-type organic transistor, a big energy gap is caused between (i) the p-type organic semiconductor layer or the n-type organic semiconductor layer and (ii) corresponding one of the source electrodes and corresponding one of the drain electrodes, so that the contact resistance is increased. In the circuit substrate disclosed in Patent Literature 2, the source electrode and the drain electrode included in one of the organic thin-film transistors is made from a material having a lower work function than that of a material of the source electrode and the drain electrode included in the other organic thin-film transistor so as to allow characteristics of the organic thin-film transistor to be fully exhibited. As such, the costs are still high due to the use of different electrode materials.

In addition, the conventional complementary logic circuit substrate cannot solve the problem that the electrode material and the organic semiconductor are in contact with each other with poor adhesiveness due to low affinity with each other, so that the efficiency in the carrier injection and the carrier extraction is lowered and the contact resistance is accordingly increased.

The present invention is accomplished in view of the aforementioned problems. An object of the present invention is to provide a semiconductor device employing organic transistors each of which has improved characteristics even in a case where electrodes of one of the organic transistors is made from a same electrode material as that of electrodes of the other organic transistor.

### Solution to Problem

In order to attain the object, a semiconductor device in accordance with the present invention is a semiconductor device including: a p-type organic transistor having a first gate electrode, a first source electrode, a first drain electrode, and a p-type organic semiconductor layer; an n-type organic transistor electrically connected with the p-type organic transistor and having a second gate electrode, a second source electrode, a second drain electrode, and an n-type organic semiconductor layer; first layers for enhancing electric charge transfer, one of the first layers being provided between the first source electrode and the p-type organic semiconductor layer, the other of the first layers being provided between the second drain electrode and the n-type organic semiconductor; and second layers which are (i) for enhancing electric charge transfer and (ii) made from a different material from that of the first layers, one of the second layers being provided between the first drain electrode and the p-type organic semiconductor layer, the other of the second layers being provided between the second source electrode and the n-type organic semiconductor layer, the first source electrode, the first drain electrode, the second source electrode, and the second drain electrode being made from a same electrode material.

Note that the expression ‘enhancing electric charge transfer’ in the description above denotes (i), when used in a situation between an organic semiconductor layer and a source electrode, which serves as an electric charge injection electrode, acceleration of injection of an electric charge from the source electrode to the organic semiconductor layer and (ii), when used in a situation between an organic semiconductor layer and a drain electrode, which serves as an electric charge extraction electrode, acceleration of extraction of an electric charge from the organic semiconductor layer.

According to the configuration, the semiconductor device in accordance with the present invention includes the p-type organic transistor having the p-type organic semiconductor layer and the n-type organic transistor having the n-type organic semiconductor layer, wherein the p-type organic transistor and the n-type organic transistor are coupled with each other. Since a first layer for enhancing electric charge transfer (electric charge injection) is provided between the source electrode of the p-type organic transistor and the p-type organic semiconductor layer, a contact resistance in an interface between the source electrode and the p-type organic semiconductor layer is reduced. This improves a mobility in the p-type transistor. Since a first layer for enhancing electric charge transfer (electric charge extraction) is provided between the drain electrode of the n-type organic transistor and the n-type organic semiconductor layer, a contact resistance in an interface between the drain electrode and the n-type organic semiconductor layer is reduced. This improves a mobility in the n-type organic transistor. Since a second layer, which is for enhancing electric charge transfer (electric charge extraction) and made from a material different from that of the first layers, is provided between the drain electrode of the p-type organic transistor and the p-type organic semiconductor layer, a contact resistance in an interface between the drain electrode and the p-type organic semiconductor layer is reduced. This improves a mobility in the p-type organic transistor. Since a second layer, which is for enhancing electric charge transfer (electric charge injection) and made from a material different from the first layers, is provided between the source electrode of the n-type organic transistor and the n-type organic semiconductor layer, a contact resistance in an interface between the source electrode and the n-type organic semiconductor layer is reduced. This improves a mobility in the n-type organic transistor.

In the p-type organic transistor, (i) the electric charge is exemplified as a hole, (ii) the first source electrode functions as a hole injection electrode, and (iii) the first drain electrode functions as a hole extraction electrode. As such, a hole in the vicinity of the first source electrode moves in a different direction from that in which a hole in the vicinity of the first drain electrode moves. However, since the first layer and the second layer are made from different materials, it is possible to select (i) a material that enhances hole injection, as the material of the first layer on the first source electrode and (ii) a material that enhances hole extraction, as the material of the second layer on the first drain electrode. Note that (i) the hole injection denotes a transfer from a work function energy level of the source electrode to a HOMO of the p-type semiconductor material and (ii) the hole extraction denotes a transfer from the HOMO of the p-type semiconductor material to a work function energy level of the drain electrode.

In the n-type organic transistor, the electric charge is exemplified as an electron and the electric charge has a reversed polarity from that of the electric charge (hole) in the p-type organic transistor. As such, the first layer on the second drain electrode functions as an enhancer of electron extraction, unlike the first layer on the first source electrode functions as an enhancer of hole injection. Likewise, the second layer on the second source electrode functions as an enhancer of electron injection, unlike the second layer on the first drain electrode functions as an enhancer of hole extraction. Note that (i) the electron injection denotes a transfer from a work function energy level of the source electrode to a LUMO of the n-type semiconductor material and (ii) the electron extraction denotes a transfer from the LUMO of the n-type semiconductor material to a work function energy level of the drain electrode.

The first source electrode, the first drain electrode, the second source electrode, and the second drain electrode are made from the same electrode material. That is, it is possible to form each of the first source electrode, the first drain electrode, the second source electrode, and the second drain electrode from a electrode material that is common to the first source electrode, the first drain electrode, the second source electrode, and the second drain electrode. This makes it possible to reduce a fabrication cost of the semiconductor device.

Since a layer for enhancing electric charge injection or a layer for enhancing electric charge extraction is provided on each of the source electrodes and on each of the drain electrode, a mobility in each of the organic transistors can be improved, even in a case where the first source electrode and the first drain electrode of the p-type organic transistor and the second source electrode and the second drain electrode of the n-type organic transistor are all made from the same material.

Thus, with the semiconductor device in accordance with the present invention, it is possible to realize a semiconductor device with excellent characteristics even in a case where the source electrode and the drain electrode of the p-type organic transistor and the source electrode and the drain electrode of the n-type organic transistor, which transistors constitute the semiconductor device, are made from an electrode material that is common to the electrodes.

In order to attain the object, a method for fabricating a semiconductor device is a method for fabricating a semiconductor device, said semiconductor device including: a p-type organic transistor having a first gate electrode, a first source electrode, a first drain electrode, and a p-type organic semiconductor layer; and an n-type organic transistor coupled with the p-type organic transistor and having a second gate electrode, a second source electrode, a second drain electrode, and an n-type organic semiconductor layer, said method preferably comprising the steps of: (a) forming first layers, one each on the first source electrode and the second drain electrode, after formation of the first source electrode and the second drain electrode and before formation of the p-type organic semiconductor layer and the n-type organic semiconductor layer, the first layers enhancing electric charge transfer; and (b) forming second layers, one each on the first drain electrode and the second source electrode, after formation of the first drain electrode and the second source electrode and before formation of the p-type organic semiconductor layer and the n-type organic semiconductor layer, the second layers enhancing electric charge transfer and being made from a different material from that of the first layers.

The configuration allows the semiconductor device to be suitably fabricated and can therefore bring about the same effect as is brought about by the semiconductor device.

Note that the order of carrying out the step for forming the first layers and the step for forming the second layers can be such that (i) the step for forming the first layers is carried out prior to the step for forming the second layers or (ii) the step for forming the second layers is carried out prior to the step for forming the first layers.

### Advantageous Effects of Invention

As described above, in the semiconductor device in accordance with the present invention, (i) the source electrodes and the drain electrodes are made from the same electrode material and (ii) layer for enhancing electric charge transfer is provided between each of the source electrodes and corresponding one of the organic semiconductor layers and between each of the drain electrodes and corresponding one of the organic semiconductor layers. This makes it possible to improve characteristics such as a mobility and a contact resistance while preventing an increase in the fabrication cost.

### BRIEF DESCRIPTION OF DRAWINGS

FIG. 1 is a cross-sectional view illustrating a schematic configuration of a semiconductor device of an embodiment of the present invention.

FIG. 2 is an equivalent circuit diagram illustrating a device circuit configuration of the semiconductor device illustrated in FIG. 1.

FIG. 3 is a view illustrating carrier transfer in the semiconductor device of an embodiment of the present invention. (a) of FIG. 3 illustrates a p-type transistor and (b) of FIG. 3 illustrates an n-type transistor.

FIG. 4 is a view illustrating a pattern of an electrode of an embodiment of the present invention.

FIG. 5 is a view illustrating a method for fabricating a semiconductor device of an embodiment of the present invention. (a) through (d) of FIG. 5 illustrate steps in a fabrication process.

FIG. 6 is a cross-sectional view illustrating a schematic configuration of a semiconductor device of a comparative example.

FIG. 7 is a view illustrating the semiconductor device illustrated in FIG. 1 and wiring connected to the semiconductor device.

FIG. 8 is a cross-sectional view illustrating a schematic configuration of a semiconductor device of another embodiment of the present invention.

FIG. 9 is a circuit diagram illustrating a device circuit configuration of the semiconductor device illustrated in FIG. 8.

FIG. 10 is a view illustrating a method for fabricating a semiconductor device of another embodiment of the present invention. (a) through (d) of FIG. 10 illustrate steps in a fabrication process.

FIG. 11 is a view illustrating the semiconductor device illustrated in FIG. 8 and wiring connected to the semiconductor device.

FIG. 12 is a view illustrating a fabrication process of an electrode in a conventional semiconductor device. (a) and (b) of FIG. 12 illustrate steps in the fabrication process.

FIG. 13 is a view illustrating (i) a configuration of a transistor constituting a conventional semiconductor device and (ii) resistances in the transistor.

FIG. 14 is a view illustrating carrier transfer in a transistor constituting a conventional semiconductor device.

FIG. 15 is a view illustrating a schematic configuration of a semiconductor device of another embodiment of the present invention. (a) of FIG. 15 illustrates a cross-section of the semiconductor device. (b) of FIG. 15 illustrates one of molecules constituting a first layer on an electrode. (c) of FIG. 15 illustrates one of molecules constituting a second layer on an electrode.

FIG. 16 is a view illustrating a method for fabricating a semiconductor device of another embodiment of the present invention. (a) through (d) of FIG. 16 illustrate steps in a fabrication process.

### DESCRIPTION OF EMBODIMENTS

### Embodiment 1

The following description will discuss, with reference to FIGS. 1 through 7, an embodiment of a semiconductor device in accordance with the present invention.

(Configuration of Semiconductor Device and Organic Transistors)

FIG. 1 is a cross-sectional view illustrating a schematic configuration of a semiconductor device of the present embodiment. As illustrated in FIG. 1, a semiconductor device 1a includes a p-type organic transistor (hereinafter simply referred to as a p-type transistor) P1 and an n-type organic transistor (hereinafter simply referred to as an n-type transistor) N1, which are provided on a same substrate 11. Each of the p-type transistor P1 and the n-type transistor N1 is a field-effect transistor whose semiconductor layer is made from an organic material.

The p-type transistor P1 is a bottom gate transistor, and includes (i) the substrate 11, (ii) a gate electrode (first gate electrode) 12 which is for the p-type transistor and is provided on the substrate 11, (iii) a gate insulating film 13 provided on the substrate 11 so as to cover the gate electrode 12, (iv) a source electrode (first source electrode) 14 which is for the p-type transistor and is provided on the gate insulating film 13, (v) a drain electrode (first drain electrode) 15 which is for the p-type transistor and is provided on the gate insulating film 13, and (vi) a p-type organic semiconductor layer (hereinafter also simply referred to as a p-type semiconductor layer) 16 provided on the gate insulating film 13, the source electrode 14, and the drain electrode 15 so as to overlap the gate electrode 12.

The p-type transistor P1 further includes a first layer 17P on the source electrode 14 and a second layer 18P on the drain electrode 15. Thus, the p-type transistor P1 has a configuration in which (i) the first layer 17P is provided between the source electrode 14 and the p-type semiconductor layer 16 and (ii) the second layer 18P is provided between the drain electrode 15 and the p-type semiconductor layer 16.

The n-type transistor N1 is a bottom gate transistor, and includes (i) the substrate 11, (ii) a gate electrode 22 (second gate electrode) which is for the n-type transistor and is provided on the substrate 11, (iii) the gate insulating film 13 provided on the substrate 11 so as to cover the gate electrode 22, (iv) a source electrode (second source electrode) 24 which is for the n-type transistor and is provided on the gate insulating film 13, (v) a drain electrode (second drain electrode) 25 which is for the n-type transistor and is provided on the gate insulating film 13, and (vi) an n-type organic semiconductor layer (hereinafter also simply referred to as an n-type semiconductor layer) 26 provided on the gate insulating film 13, the source electrode 24, and the drain electrode 25 so as to overlap the gate electrode 22.

The n-type transistor N1 further includes a first layer 17N on the drain electrode 25 and a second layer 18N on the source electrode 24. Thus, the n-type transistor N1 has a configuration in which (i) the first layer 17N is provided between the drain electrode 25 and the n-type semiconductor layer 26 and (ii) the second layer 18N is provided between the source electrode 24 and the n-type semiconductor layer 26.

In the semiconductor device 1a, not only the substrate 11 but also the gate insulating film 13 is shared by the p-type transistor P1 and the n-type transistor N1.

The semiconductor device 1a has a configuration in which the drain electrode 15 of the p-type transistor P1 and the drain electrode 25 of the n-type transistor N1 are electrically connected with each other. The present embodiment employs a configuration in which the drain electrode 15 and the drain electrode 25 are electrically connected with each other by being physically in contact with each other. Note, however, that the present invention can employ a configuration in which the drain electrode 15 and the drain electrode 25 are physically separated from each other but electrically connected with each other via other metal wiring.

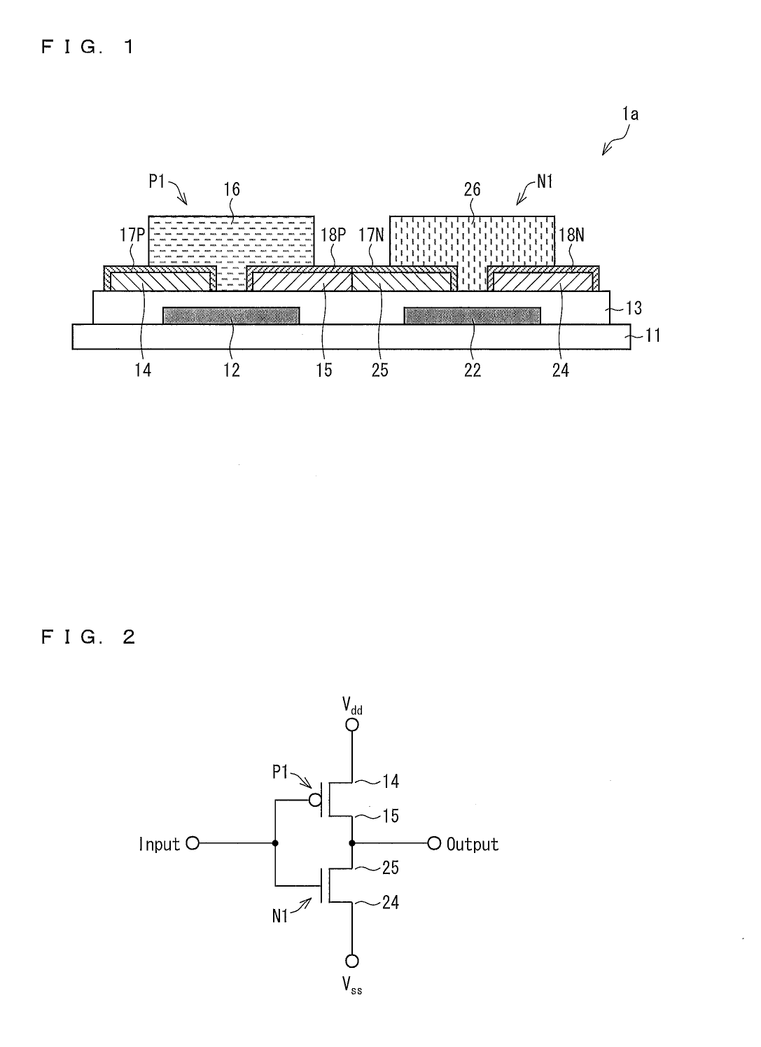

FIG. 2 is an equivalent circuit diagram illustrating a device circuit of the semiconductor device 1a. The semiconductor device 1a has a gate structure in which the p-type transistor P1 and the n-type transistor N1 are connected with each other in a complementary manner. As is clear from FIG. 2, the semiconductor device 1a constitutes an inverter circuit like a CMOS circuit.

As illustrated in FIG. 2, the p-type transistor P1 and the n-type transistor N1 are provided in the semiconductor device 1a so that the source electrode 14 of the p-type transistor P1, the drain electrode 15 of the p-type transistor P1, the drain electrode 25 of the n-type transistor N1, and the source electrode 24 of the n-type transistor N1 are electrically connected in this order between terminals Vdd and Vss. That is, the semiconductor device 1a functions as the inverter circuit in which a positive voltage is applied to the terminal Vdd.

(First Layers and Second Layers)

Each of the first layer 17P and the second layer 18P in the p-type transistor P1 is a layer for enhancing electric charge transfer. Specifically, the first layer 17P between the source electrode 14 and the p-type semiconductor layer 16 is a layer for enhancing injection of an electric charge (in this case, a hole h⁺) from a work function energy level of the source electrode 14 to a HOMO of the p-type semiconductor layer 16. The second layer 18P between the drain electrode 15 and the p-type semiconductor layer 16 is a layer for enhancing extraction of an electric charge (a hole h⁺) from the HOMO of the p-type semiconductor layer 16 to a work function level of the drain electrode 15. Such being the case, the first layer 17P and the second layer 18P are made from respective different materials.

Each of the first layer 17N and the second layer 18N in the n-type transistor N1 is a layer for enhancing electric charge transfer as well. Specifically, the first layer 17N between the drain electrode 25 and the n-type semiconductor layer 26 is a layer for enhancing extraction of an electric charge (in this case, an electron e⁻) from a LUMO (Lowest Unoccupied Molecular Orbital) of the n-type semiconductor layer 26 to the drain electrode 25. The second layer 18N between the source electrode 24 and the n-type semiconductor layer 26 is a layer for enhancing injection of an electric charge (an electron e⁻) from a work function energy level of the source electrode 24 to the LUMO of the n-type semiconductor layer 26. Such being the case, the first layer 17N and the second layer 18N are made from respective different materials.

It is preferable that the first layers 17P and 17N be made from a same material and the second layers 18P and 18N be made from a same material. In such a case, it is only necessary to use two types of materials, that is, a material suitable for the first layers and another material suitable for the second layers. This allows a reduction in material cost, the number of fabrication processes, and ultimately fabrication cost.

Each of the layers 17P, 17N, 18P, and 18N having the functions above can be formed by use of molecules each having an electric dipole moment.

Examples of a molecule which has an electric dipole moment and can be used as, for example, (i) the first layer 17P that enhances the injection of the hole h⁺ into the p-type semiconductor layer 16 and (ii) the first layer 17N that enhances the extraction of the electron e⁻ from the n-type semiconductor layer 26, encompass a molecule expressed by General Formula (1):

X-A-Y¹ (1)

(where X is a functional group capable of binding to each of the atoms constituting the electrodes (the source electrodes 14 and 24 and the drain electrodes 15 and 25), A is a π-conjugated moiety or an aliphatic moiety, and Y¹ is an electron withdrawing group).

X in General Formula (1) is a functional group that allows the molecule represented by General Formula (1) to bind to an atom (electrode material) constituting the source electrode 14 or an atom (electrode material) constituting the drain electrode 25. Specifically, X is a thiol group (—SH), a silane coupling group (—SiR¹³), a phosphonate moiety (—POR²₂), a carboxylate moiety (—COOH), a nitrile group (—CN), or a monoalkylsilane moiety (—SiH₃). In the silane coupling group, at least one of the three R¹ is a methoxy group (—OMe), an ethoxy group (—OEt), and a chloro group (—Cl), each of which is involved in the binding, and the other(s) of the three R¹ is(are) hydrogen or a methyl group, each of which is uninvolved in the binding. In the phosphonate moiety, at least one of the two R² is a hydroxy group (—OH) or a chloro group (—Cl) and the other is a methyl group or a methoxy group uninvolved in the binding.

The molecule constituting the first layer 17P or 17N is bound to the corresponding one of the electrode materials by means of the binding between the functional group X and the electrode material. This makes it possible to improve durability of the first layers.

Particularly, in a case where the electrode material is gold, silver, or aluminum, X is preferably a thiol group, a nitrile group, or a monoalkylsilane moiety. Especially, in a case where X is a thiol group or a monoalkylsilane moiety, the electrode material is connected, solely via a single atom (a sulfur atom in the case of a thiol group and a silicon atom in the case of a monoalkylsilane moiety), with the molecule constituting the first layer. This causes a reduction in a distance between the electrode and the molecule constituting the first layer. As such, a contact resistance is reduced in an interface between the electrode material and the first layer. In a case where a hydroxy group is present on a surface of the electrode, X is preferably a silane coupling moiety, a phosphonate moiety, or a carboxylate moiety. Especially, in a case where X is a silane coupling moiety or a phosphonate moiety, a covalent bond acts between an atom of the electrode material and an oxygen atom of a silane coupling agent or between an atom of the electrode material and an oxygen atom of a phosphonic acid. This allows the first layer to be more securely fixed on the electrode. Since the covalent bond is generally stronger than a gold-thiol bond, it becomes possible to attain a longer lifespan.

A in General Formula (1) constitutes a main chain backbone of the molecule expressed by General Formula (1). A is (i) a π-conjugated moiety having a plurality of π-electrons in its molecule or (ii) an aliphatic moiety having, in its molecule, an aliphatic backbone having a σ-electron.

The π-conjugated moiety is not limited to a specific one. Examples of the π-conjugated moiety encompass an aromatic compound having (i) a monocyclic structure such as benzene, pyridine, thiophene, or pyrrole as shown in (a) through (d) of Chemical Formula (I), (ii) a ring-fused structure such as naphthalene, anthracene, tetracene, or pentacene as shown in (e) through (h) of Chemical Formula (II), and (iii) a polycyclic framework such as biphenyl, bipyridyl, terphenyl, or terthiophene as shown in (i) through (l) of Chemical Formula (III).

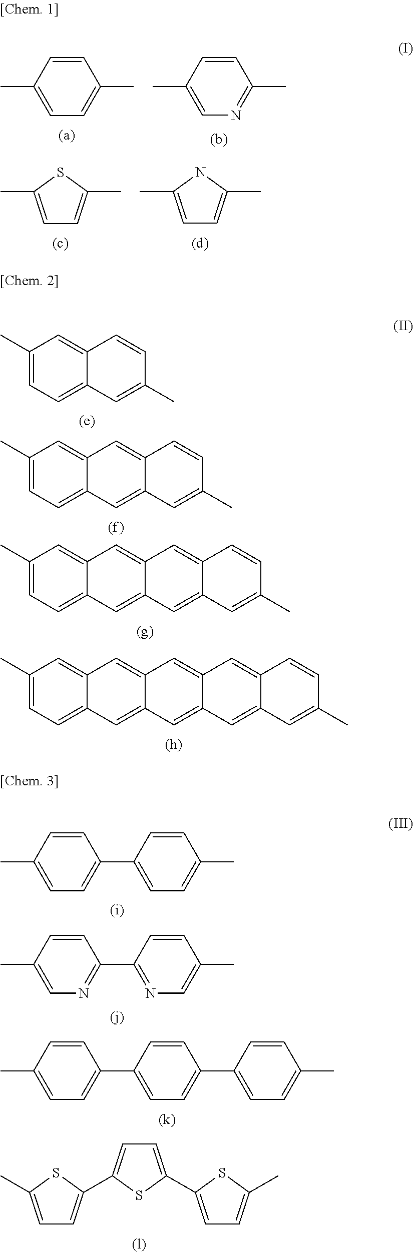

The aliphatic moiety is not limited to a specific one. Examples of the aliphatic moiety encompass a C₁₋₂₀ linear alkane as shown in Chemical Formula (IV). A linear alkane has a smaller molecular cross-section than that of an aromatic backbone and therefore makes it possible to form a self-assembled monolayer having a high molecular density. This causes an increase in the number of molecules per unit area which molecules each have an electric dipole moment. It therefore becomes possible to improve carrier injection effect and carrier extraction effect. In addition, by limiting the number of carbon atoms of the linear alkane to be not more than 20, it becomes possible to prevent (i) an increase in resistance of the self-assembled monolayer itself and (ii) an increase in contact resistance in the interface between the organic semiconductor layer and the source electrode and in the interface between the organic semiconductor layer and the drain electrode.

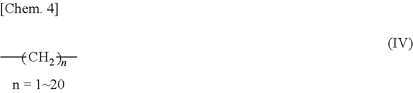

Y¹ in General Formula (1) is a site of the molecule expressed by General Formula (1), which site, serving as a surface of the first layer, is in contact with the organic semiconductor layer. Y¹ in each of the first layers 17P and 17N is preferably an electron withdrawing group.

In a case where Y¹ is an electron withdrawing group, a portion of the molecule expressed by General Formula (1), which portion is in the vicinity of a substituent group Y¹, is negatively charged. This causes the molecule constituting the first layer to be polarized. That is, in a case where Y¹ is an electron withdrawing group, the molecule constituting the first layer has an electric dipole moment pointing in a direction from Y¹ toward X. The molecule constituting the first layer binds, at X, to the electrode and is in contact, at Y¹, with the organic semiconductor layer. Thus, each of the first layers 17P and 17N is constituted by molecules each having an electric dipole moment pointing in a direction from corresponding one of the organic semiconductor layers toward corresponding one of the electrodes to which the first layer 17P or 17N binds.

Note that ‘direction of an electric dipole moment’ in the Description is defined as a direction of a vector from the negative pole toward the positive pole of a polarized material.

Note that ‘electron withdrawing group’ and ‘electron donating group’ in the Description denote (i) a group with a Hammett substituent constant having a negative value and (ii) a group with a Hammett substituent constant having a positive value, respectively.

Y¹ is not limited to a specific one. Examples of Y¹ encompass a halogen group (—F, —Br, —Cl, and —I), a nitro group (—NO₂), a cyano group (—CN), an alkoxysilane group (—Si(OR³)₃), a trifluoromethyl group (—CF₃), a chloromethyl group (—CH₂Cl), an aldehyde group (—CHO), and an alkoxycarbonyl group (—COOR⁴). R³ and R⁴ each represent a C₁₋₃ straight-chain alkyl group.

Among them, Y¹ is preferably a nitro group. In a case where Y¹ is a nitro group (and X is thiol and A is an aromatic ring), the electric dipole moment has a relatively large absolute value of 4.93 D (Debye: 1 D=3.33564×10⁻³⁰ C·m). This enhances effect of decreasing the contact resistance.

Particularly, the molecule that constitutes each of the first layers 17P and 17N is preferably p-nitrobenzenethiol.

Examples of a molecule which has an electric dipole moment and can be used as, for example, (i) the second layer 18P that enhances the extraction of the hole h⁺ from the p-type semiconductor layer 16 and (ii) the second layer 18N that enhances the injection of the electron e⁻ into the n-type semiconductor layer 26, encompass a molecule expressed by General Formula (2):

X-A-Y² (2)

(where X is a functional group capable of binding to atoms constituting the respective electrodes, A is a π-conjugated moiety or an aliphatic moiety, and Y² is an electron donating group).

X and A in General Formula (2) are similar to X and A in General Formula (1) and therefore descriptions on X and A in General Formula (2) will be omitted.

Y² in General Formula (2) is a site of the molecule expressed by General Formula (2), which site, serving as a surface of the second layer, is in contact with the organic semiconductor layer. Y² in each of the second layers 18P and 18N is preferably an electron donating group.

In a case where Y² is an electron donating group, a portion of the molecule expressed by General Formula (2), which portion is in the vicinity of a substituent group Y², is positively charged. This causes the molecule constituting the second layer to be polarized. That is, in a case where Y² is an electron donating group, the molecule constituting the second layer has an electric dipole moment pointing in a direction from X toward Y². The molecule constituting the second layer binds, at X, to the electrode and in contact, at Y², with to the organic semiconductor layer. Thus, each of the second layers 18P and 18N is constituted by molecules each having an electric dipole moment pointing in a direction from (i) corresponding one of the electrodes to which the second layer 18P or 18N binds toward (ii) corresponding one of the organic semiconductor layers (i.e., reverse to the direction of the dipole moment of each molecule constituting the first layers 17P and 17N).

Y² is not limited to a specific one. Examples of Y² encompass a hydroxy group (—OH), an alkoxy group (−OR⁵), an amino group (—NH₂, —NHR⁶, —NR⁷R⁸), a thiol group (—SH), an alkylthio group (—SR⁹), and an alkyl group (—R¹⁰). R⁵ through R¹⁰ each represents a C₁₋₃ straight-chain alkyl group.

Among them, Y² is preferably an amino group. In a case where Y² is —NH₂ or —N(CH₃)₂ (and X is thiol and A is an aromatic ring), the electric dipole moment has a relatively large absolute value of 3.10 D (with —NH₂) and 3.96 D (with —N(CH₃)₂). This enhances an effect of decreasing the contact resistance.

Particularly, the molecule that constitutes each of the second layers 18P and 18N is preferably p-aminobenzenethiol or p-dimethylaminobenzenethiol.

The molecule expressed by General Formula (1) and the molecule expressed by General Formula (2) each have (i), at one end of the molecule in a longitudinal direction, a functional group capable of binding to the electrode material and (ii), at the other end, an electron withdrawing group or an electron donating group. This allows a self-assembled monolayer (SAM) to be formed on each of the electrodes, so that an electron withdrawing group or an electron donating group is arranged on an opposite side of the electrode. Since orientations of the molecules are controlled in the self-assembled monolayer, the directions of the electric dipole moments of the respective molecules can be aligned. This makes it possible to enhance an electric charge injection effect or an electric charge extraction effect, which are brought about by the electric dipole moments.

Each of the self-assembled monolayers has a film thickness substantially equal to a molecular length of the molecules that constitute the self-assembled monolayer. As such, a thickness of each of the first layers 17P and 17N and the second layers 18P and 18N can be made as small as the molecular length of the molecules that constitutes corresponding one of the self-assembled monolayers. This allows a reduction in (i) the resistance of each of the first layers 17P and 17N themselves and (ii) the resistance of each of the second layers 18P and 18N themselves.

Note that each of the first layers 17P and 17N and the second layers 18P and 18N is not limited to a specific one, provided that it is made from a material which has an electric dipole moment and in which orientations of the electric dipole moments of molecules are aligned. Such being the case, examples of the molecule constituting each of the first layers 17P and 17N and the second layers 18P and 18N encompass, other than the molecule that constitutes a self-assembled monolayer, an inorganic material such as lithium fluoride and molybdenum oxide.

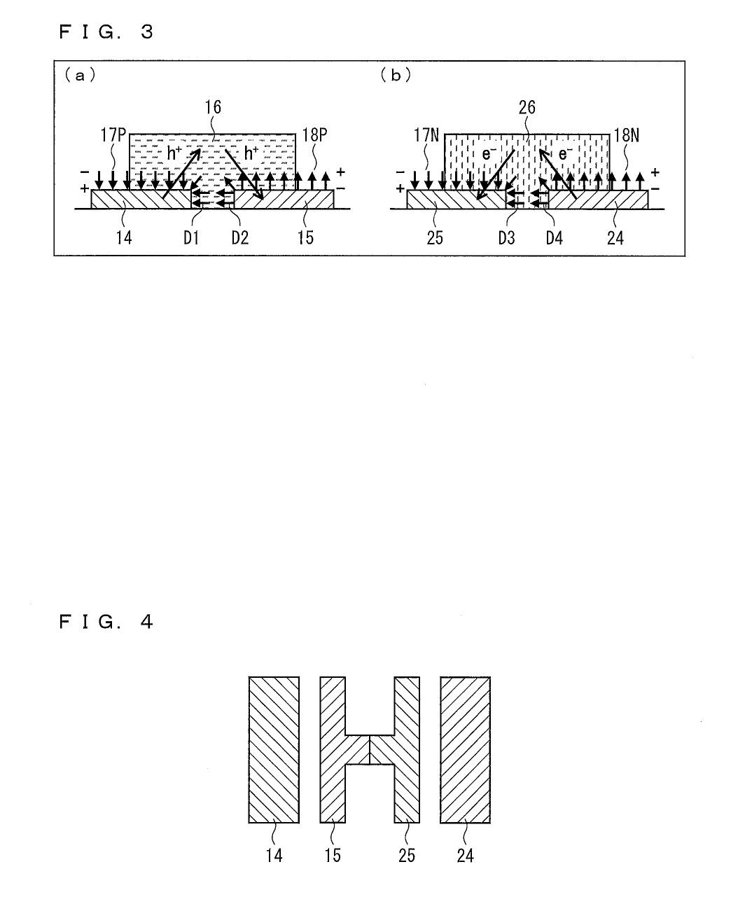

Next, the following description will discuss, with reference to FIG. 3, how the first layer 17P and the second layer 18P function in the organic transistor P1 and how the first layer 17N and the second layer 18N function in the organic transistor N1 in the semiconductor device 1a.

(a) of FIG. 3 is a view for illustrating how the first layer 17P and the second layer 18P work in the organic transistor P1. For convenience, (a) of FIG. 3 omits the substrate 11, the gate electrode 12, and the gate insulating film 13. In the organic transistor P1, a hole h⁺ serves as the carrier. Each of the first layer 17P and the second layer 18P is illustrated by arrows each indicating a direction of each of the electric dipole moments in the first layer 17P or the second layer 18P. In the organic transistor P1, each of the first layer 17P and the second layer 18P forms a self-assembled monolayer.

As illustrated in (a) of FIG. 3, in the first layer 17P provided on the source electrode 14, the electric dipole moment of each of the molecules constituting the self-assembled monolayer points in a direction D1 from the p-type semiconductor layer 16 toward the source electrode 14. Note that a hole h⁺ is easily released from a surface (source for supplying hole h⁺) of an electrode to an external layer, in a case where (i) the hole h⁺ is injected from the electrode into an organic semiconductor layer and (ii) there is provided, between the electrode (hole injection electrode) and the organic semiconductor layer, a layer whose electric dipole moment points in a direction reverse to a direction in which the hole h⁺ moves. This is made possible by the electric double layer effect. That is, it is possible to improve efficiency in injection of holes from the source electrode 14 into the p-type organic semiconductor layer 16. In addition, in terms of the band theory, the energy gap between the energy level of the work function of the source electrode 14 and the HOMO of the p-type semiconductor layer 16 is reduced in a case of inserting, in the interface between the source electrode 14 and the organic semiconductor layer 16, the electric dipole moment pointing in a direction from the organic semiconductor layer toward the source electrode. Since the provision of the first layer 17P causes a reduction in the contact resistance, a mobility in the organic transistor P1 is improved.

In contrast, in the second layer 18P provided on the drain electrode 15, the electric dipole moment of each of the molecules constituting the self-assembled monolayer points in a direction D2 from the drain electrode 15 toward the p-type semiconductor layer 16. Note that a hole h⁺ is easily released from an organic semiconductor layer, which holds the hole h⁺, to an external layer, in a case where (i) the hole h⁺ is extracted from the organic semiconductor layer by an electrode and (ii) there is provided, between the electrode (hole extraction electrode) and the organic semiconductor layer, a layer whose electric dipole moment points in a direction reverse to a direction in which the hole h⁺ moves. This is made possible by the electric double layer effect. That is, it is possible to improve efficiency in extraction of holes from the p-type organic semiconductor layer 16 into the drain electrode 15. Since the provision of the second layer 18P causes a reduction in the contact resistance, a mobility in the organic transistor P1 is improved.

The provision of the layers 17P and 18P causes an improvement in (i) efficiency in the carrier injection at the source electrode 14 of the p-type transistor P1 and (ii) efficiency in the carrier extraction at the drain electrode 15 of the p-type transistor P1 in the semiconductor device 1a. This causes a reduction in the contact resistance.

(b) of FIG. 3 is a view for illustrating how the first layer 17N and the second layer 18N work in the organic transistor N1. For convenience, (b) of FIG. 3 omits the substrate 11, the gate electrode 22, and the gate insulating film 13. In the organic transistor N1, an electron e⁻ serves as the carrier. Each of the first layer 17N and the second layer 18N is illustrated by arrows each indicating a direction of each of the electric dipole moments in the first layer 17N or the second layer 18N. In the organic transistor N1, each of the first layer 17N and the second layer 18N forms a self-assembled monolayer.

As illustrated in (b) of FIG. 3, in the first layer 17N provided on the drain electrode 25, the electric dipole moment of each of the molecules constituting the self-assembled monolayer points in a direction D3 from the n-type semiconductor layer 26 toward the drain electrode 25. Note that an electron e⁻ is easily released from an organic semiconductor layer, which holds the electron e⁻, to an external layer, in a case where (i) the electron e⁻ is extracted from the organic semiconductor layer by an electrode and (ii) there is provided, between the electrode (electron extraction electrode) and the organic semiconductor layer, a layer whose electric dipole moment points in a direction equal to a direction in which the electron e⁻ moves. This is made possible by the electric double layer effect. That is, it is possible to improve efficiency in extraction of electrons from the n-type organic semiconductor layer 26 into the drain electrode 25. Since the provision of the first layer 17N causes a reduction in the contact resistance, a mobility in the organic transistor N1 is improved.

In contrast, in the second layer 18N provided on the source electrode 24, the electric dipole moment of each of the molecules constituting the self-assembled monolayer points in a direction D4 from the source electrode 24 toward the n-type semiconductor layer 26. Note that an electron e⁻ is easily released from an electrode (source for supplying electron e⁻) to an external layer, in a case where (i) the electron e⁻ is injected from the electrode into an organic semiconductor layer and (ii) there is provided, between the electrode (electron injection electrode) and the organic semiconductor layer, a layer whose electric dipole moment points in a direction equal to a direction in which the electron e⁻ moves. This is made possible by the electric double layer effect. That is, it is possible to improve efficiency in injection of electrons from the source electrode into the n-type organic semiconductor layer 26. In addition, in terms of the band theory, the energy gap between the energy level of the work function of the source electrode 24 and the LUMO of the n-type semiconductor layer 26 is reduced in a case of inserting, in the interface between the source electrode 24 and the organic semiconductor layer 26, the electric dipole moment pointing in a direction from the source electrode toward the organic semiconductor layer. Since the provision of the second layer 18N causes a reduction in the contact resistance, a mobility in the organic transistor N1 is improved.

The provision of the layers 17N and 18N causes an improvement in (i) efficiency in the carrier injection at the source electrode 24 of the n-type transistor N1 and (ii) efficiency in the carrier extraction at the drain electrode 25 of the n-type transistor N1 in the semiconductor device 1a. This causes a reduction in the contact resistance.

As described above, (i) the first layer 17P provided in the p-type transistor P1 and (ii) the first layer 17N provided in the n-type transistor N1, have respective different functions although they are made from the same material. Likewise, (i) the second layer 18P provided in the p-type transistor P1 and (ii) the second layer 18N provided in the n-type transistor N1, have respective different functions although they are made from the same material. The functions of the respective layers 17P, 17N, 18P and 18N are shown in Table 1.

TABLE 1

| | p-type transistor | n-type transistor |
|---|---|---|
| First layer | Electron injection | Electron extraction |
| | improvement | improvement |
| Second layer | Electron extraction | Electron injection |
| | improvement | improvement |

(Organic Semiconductor Layer)

Each of the organic semiconductor layers can be made from a conventionally known organic semiconductor material having a p-type characteristic or an n-type characteristic. Examples of the p-type organic semiconductor material from which the p-type semiconductor layer 16 is made encompass pentacene, rubrene, oligothiophene, polythiophene, and their alkyl-substituted derivatives. Among them, pentacene is preferable because pentacene allows the carrier to have a high mobility.

Examples of the n-type organic semiconductor material from which the n-type semiconductor layer 26 is made encompass fullerene (C60), pentacene fluoride, and a perylene imide compound. Among them, fullerene (C60) is preferred because fullerene (C60) allows the carrier to have a high mobility.

(Electrode Material)

Examples of the electrode material of each of the gate electrodes 12 and 22, the source electrodes 14 and 24, and the drain electrodes 15 and 25 encompass (i) a metal material such as gold (Au), silver (Ag), copper (Cu), platinum (Pt), palladium (Pd), iron (Fe), aluminum (Al), tantalum (Ta), and chromium (Cr), (ii) their alloyed materials, and (iii) oxide conductors such as indium tin oxide (ITO), indium zinc oxide (IZO), zinc oxide (ZnO), and tin oxide (SnO₂). Particularly, each of the source electrodes 14 and 24 and the drain electrodes 15 and 25 is preferably made from Au, Ag, ITO, IZO, ZnO, or SnO₂. Each of these electrode materials and the molecule constituting corresponding one of the layers easily form a chemical bond, so that it is possible to form efficiently a self-assembled monolayer on the surface of the electrode.

In the conventional complementary logic circuit in which a plurality of organic transistors are provided in combination, it is necessary that a constituent material of a source electrode of and a drain electrode of one of the plurality of organic transistors have a work function lower than that of a constituent material of a source electrode of and a drain electrode of the other of the plurality of organic transistors, in order to enhance a switching characteristic.

In contrast, in the semiconductor device 1a, (i) the first layer 17P and the second layer 18P are provided between (a) the organic semiconductor layer 16 and (b) respective of the source electrode 14 and the drain electrode 15 and (ii) the first layer 17N and the second layer 18N are provided between (c) the organic semiconductor layer 26 and (d) respective of the drain electrode 25 and the source electrode 24, so that the carrier injection and the carrier extraction are enhanced. This allows the source electrode 14 and the drain electrode 15 to be made from the same electrode material as that of the source electrode 24 and the drain electrode 25. As later described, even though the electrodes are made from the same electrode material, there occurs no deterioration in (i) the characteristics of the semiconductor device 1a and (ii) the characteristics of each of the organic transistors P1 and N1.

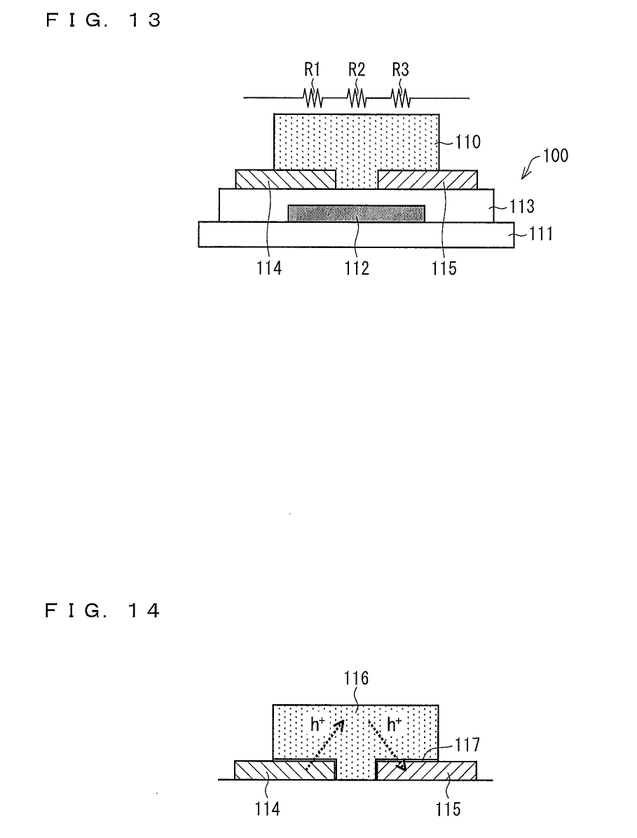

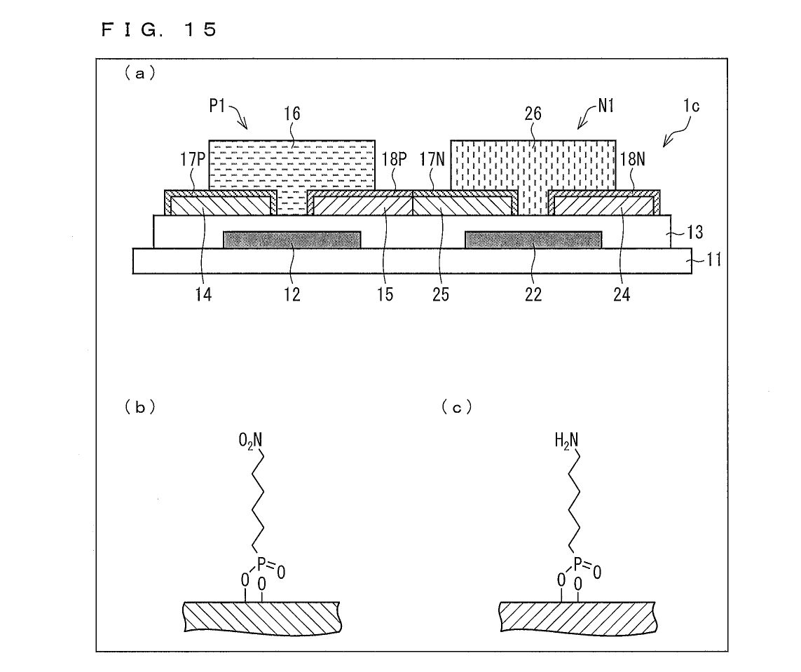

FIG. 4 is a view illustrating deposition patterns of the source electrodes and the drain electrodes. Conventionally, as illustrated in FIG. 12, in a case where a complementary logic circuit is fabricated by use of two organic transistors, it has been necessary to (i) first form and pattern the source electrode 114 of and the drain electrode 115 of one of the two organic transistors (see (a) of FIG. 12) and then (ii) form and pattern the source electrode 124 of and the drain electrode 125 of the other of the two organic transistors (see (b) of FIG. 12).

In contrast, in a case where the semiconductor device 1a is fabricated, it is possible to concurrently form and pattern (i) the source electrode 14 and the drain electrode 15 of one of the two organic transistors and (ii) the source electrode 24 and the drain electrode 25 of the other of the two organic transistors, as illustrated in FIG. 4. This is possible because all the electrodes can be made from the same electrode material. Note that, in fabrication of the first layers 17P and 17N and the second layers 18P and 18N, the first layers 17P and 17N are formed selectively on the source electrode 14 and the drain electrode 25, respectively, by means of known photolithography. The second layers 18N and 18P are subsequently formed on the source electrode 24 and the drain electrode 15, respectively.

(Substrate Material)

The substrate 11 is not limited to a specific one. Examples of the substrate 11 encompass (i) substrates each made from an inorganic material such as a silicon substrate, a quartz substrate, or a glass substrate and (ii) resin substrates each made from an organic material such as polycarbonate, polyether ether ketone, polyimide, polyester, or polyether sulfone. Among them, the resin substrate is preferable. The resin substrate has flexibility and can therefore be suitably applied to a flexible device in particular.

(Method for Fabricating Semiconductor Device)

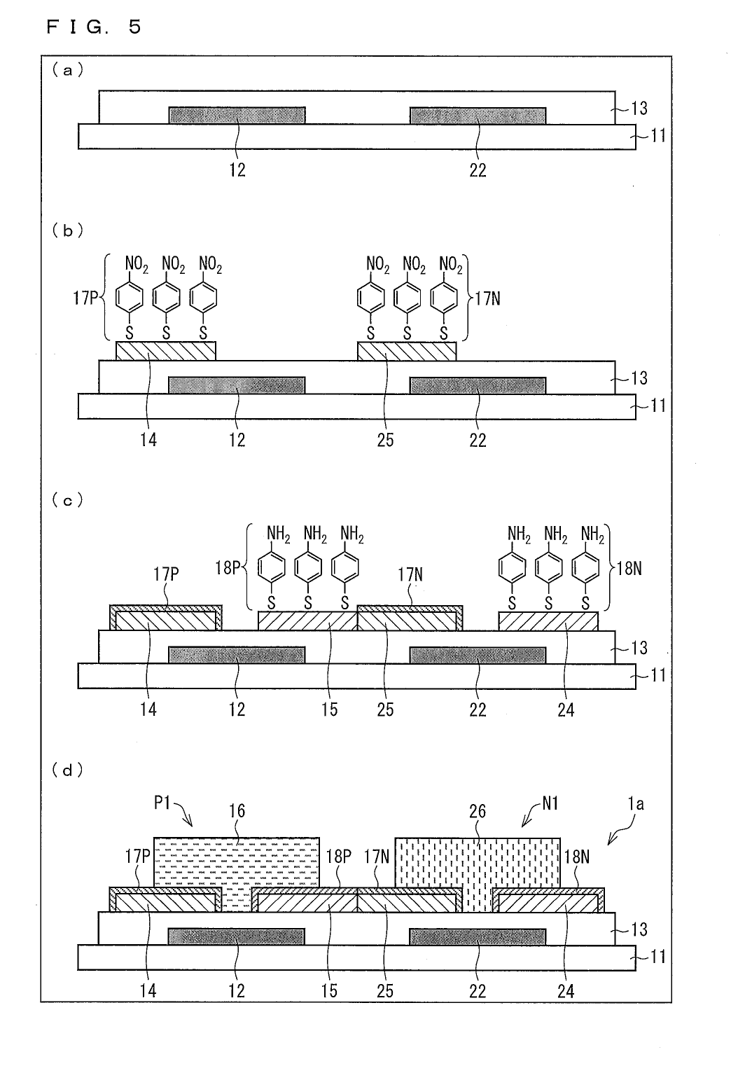

A method for fabricating a semiconductor device in accordance with the present embodiment is a method for fabricating a semiconductor device, said semiconductor device including: a p-type organic transistor having a first gate electrode, a first source electrode, a first drain electrode, and a p-type organic semiconductor layer; an n-type organic transistor coupled with the p-type organic transistor and having a second gate electrode, a second source electrode, a second drain electrode, and an n-type organic semiconductor layer, said method including the steps of: (a) forming first layers, one each on the first source electrode and the first drain electrode, after formation of the first source electrode and the second drain electrode and before formation of the p-type organic semiconductor layer and the n-type organic semiconductor layer, the first layers enhancing electric charge transfer; and (b) forming second layers, one each on the first drain electrode and the second source electrode, after formation of the first drain electrode and the second source electrode and before formation of the p-type organic semiconductor layer and the n-type organic semiconductor layer, the second layers enhancing electric charge transfer. The method can be suitably applied to fabrication of the semiconductor device 1a. The following description will concretely discuss a method for fabricating the semiconductor device 1a with reference to FIG. 5.

(a) through (d) of FIG. 5 are views schematically illustrating steps in a fabrication process in accordance with the present embodiment.

Initially, as illustrated in (a) of FIG. 5, an aluminum film with a film thickness of 60 nm is formed on the entire surface of a glass substrate (substrate size: 25 mm×25 mm) (substrate 11) by sputtering and the aluminum film thus formed is patterned by means of known photolithography, so that the gate electrodes 12 and 22 are formed. Subsequently, a silicon dioxide film with a film thickness of 200 nm is formed on the glass substrate 11 by sputtering so as to cover the gate electrodes 12 and 22. The silicon dioxide film thus formed serves as the gate insulating film 13.

Next, after formation of the gate insulating film 13, a film of chromium with a film thickness of 5 nm and a film of gold with a film thickness of 60 nm are formed in this order on the gate insulating film 13 by means of vacuum vapor deposition via a metal mask, so that the source electrode 14 of the p-type transistor and the drain electrode 25 of the n-type transistor are formed. Note that chromium plays a role of causing gold and the gate insulating film 13 to adhere to each other.

A 1 mM anhydrous ethanol solution of p-nitrobenzenethiol is prepared. The substrate on which the source electrode 14 and the drain electrode 25 are formed is immersed in the 1 mM anhydrous ethanol solution of p-nitrobenzenethiol for 3 hours. Since p-nitrobenzenethiol has a function of forming a SAM, a SAM of p-nitrobenzenethiol is formed on each of the source electrode 14 and the drain electrode 25. In each SAM, a thiol group and gold of the source electrode 14 or the drain electrode 25 form a chemical bond. That is, the first layers 17P and 17N each made from a SAM of p-nitrobenzenethiol are formed on the source electrode 14 and the drain electrode 25, respectively ((b) of FIG. 5). Note that it is preferable that the substrate, which has been immersed for 3 hours, be rinsed with anhydrous ethanol so as to remove p-nitrobenzenethiol excessively adsorbed.

Next, a film of chromium with a film thickness of 5 nm and a film of gold with a film thickness of 60 nm are formed in this order on the gate insulating film 13 by means of vacuum vapor deposition via a metal mask, so that the drain electrode 15 of the p-type transistor and the source electrode 24 of the n-type transistor are formed. Again, chromium plays a role of causing gold and the gate insulating film 13 to adhere to each other.

At this time, the drain electrode 15 is formed so as to be in contact with, that is, electrically connected with the drain electrode 25 which has been already formed. Note that, although the drain electrode 25 and the drain electrode 15 are physically in contact with each other via the first layer 17N, the first layer 17N is an extremely thin film with a thickness of about 1 nm and can therefore be ignored in terms of electric resistance. Thus, the drain electrode 25 and the drain electrode 15 are electrically connected with each other.

Note that, in the present embodiment, the plurality of semiconductor devices, which differ in channel length of their respective transistors, are prepared on the same substrate. That is, the electrodes are formed so that each of the p-type transistor P1 and the n-type transistor N1, which are to be ultimately formed, has a channel length of 30 μm, 40 μm, 50 μm, 75 μm, or 100 μm and a channel width of 1000 μm.

After the drain electrode 15 and the source electrode 24 are formed, a 1 mM anhydrous ethanol solution of p-aminobenzenethiol is prepared. The substrate on which the drain electrode 15 and the source electrode 24 are formed is immersed in the 1 mM anhydrous ethanol solution of p-aminobenzenethiol for 3 hours. Since p-aminobenzenethiol has a function of forming a SAM, a SAM of p-aminobenzenethiol is formed on each of the drain electrode 15 and the source electrode 24. In each SAM, a thiol group and gold of the drain electrode 15 or the source electrode 24 form a chemical bond. That is, the second layers 18P and 18N each made from a SAM of p-aminobenzenethiol are formed on the drain electrode 15 and the source electrode 24, respectively ((c) of FIG. 5). Note that it is preferable that the substrate, which has been immersed for 3 hours, be rinsed with anhydrous ethanol so as to remove p-aminobenzenethiol excessively adsorbed.

Next, as illustrated in (d) of FIG. 5, a film of pentacene with a film thickness of 60 nm, which film serves as the p-type semiconductor layer 16, is formed, by vacuum vapor deposition via a metal mask, in an area overlapping the gate electrode 12. Thus, the p-type transistor P1 of the semiconductor device 1a is formed.

Subsequently, a film of fullerene (C60) with a film thickness of 60 nm, which film serves as the n-type semiconductor layer 26, is formed, by vacuum vapor deposition via a metal mask, in an area overlapping the gate electrode 22. Thus, the n-type transistor N1 of the semiconductor device 1a is formed.

In this way, it is possible to fabricate the semiconductor device 1a that constitutes a complementary logic circuit in which the p-type transistor P1 and the n-type transistor N1 are connected with each other in a complementary manner.

According to the method for fabricating the semiconductor device of the present embodiment, (i) the source electrode 14 of the p-type transistor P1 and the drain electrode 25 of the n-type transistor N1 are formed at the same time and (ii) the drain electrode 15 of the p-type transistor P1 and the source electrode 24 of the n-type transistor N1 are formed at the same time. This makes it possible to reduce the number of steps in the fabrication process.

According to the method for fabricating the semiconductor device of the present embodiment, all of the source electrodes and the drain electrodes used in the p-type transistor P1 and the n-type transistor N1 are made from the same material. This makes it possible to reduce a fabrication cost.

Note that, although (a) the drain electrode 15 and the source electrode 24 and (b) the second layers 18P and 18N are formed after (c) the source electrode 14 and the drain electrode 25 and (d) the first layers 17P and 17N are formed in the present embodiment, the order of formations can be reversed. Specifically, it is possible that (i) the second layers 18P and 18N are formed after (ii) the drain electrode 15 and the source electrode 24 are formed, and then (iii) the first layers 17P and 17N are formed after (iv) the source electrode 14 and the drain electrode 25 are formed.

According to the present embodiment, the n-type semiconductor layer 26 is formed after the p-type semiconductor layer 16 is formed. The present embodiment is not limited to this order of formations. Specifically, it is possible that the p-type semiconductor layer 16 is formed after the n-type semiconductor layer 26 is formed.

(Characteristics of Organic Transistor and Semiconductor Device)

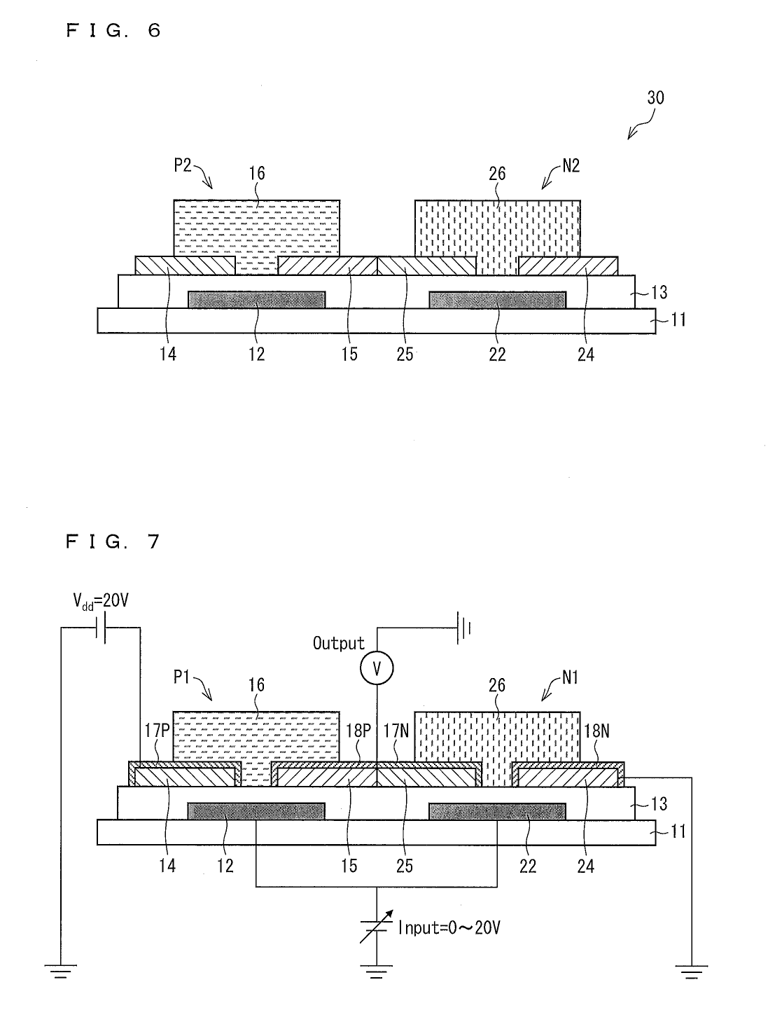

Next, the following description will discuss, with reference to FIGS. 6 and 7, (i) characteristics of the semiconductor device 1a and (ii) characteristics of the p-type transistor P1 and the n-type transistor N1 which constitute the semiconductor device 1a.

FIG. 6 is a view illustrating a schematic configuration of a semiconductor device of a comparative example. A semiconductor device 30 of the comparative example is a semiconductor device constituted by a p-type organic transistor P2 and an n-type organic transistor N2, which are electrically connected with each other via a drain electrode 15 of the p-type organic transistor P2 and a drain electrode 25 of the n-type organic transistor N2. The semiconductor device 30 has the same configuration as that of the semiconductor device 1a except that the semiconductor device 30 includes no first layers 17P and 17N and no second layers 18P and 18N, unlike the semiconductor device 1a. As such, the semiconductor device 30 is a semiconductor device fabricated by use of the same materials and by the same procedures as those employed in the fabrication of the semiconductor device 1a, except that no first layers 17P and 17N and no second layers 18P and 18N are formed in the fabrication process of the semiconductor device 30.

Initially, characteristics (mobility and ON/OFF ratio) of a device in each of the p-type transistor P1 and the n-type transistor N1 were determined. Results showed that the device in the p-type transistor P1 had a mobility of 0.8 cm²/V·s and an ON/OFF ratio of 10⁶ and the device in the n-type transistor N1 had a mobility of 0.7 cm²/V·s and an ON/OFF ratio of 10⁶.

In contrast, characteristics of a device in each of the p-type transistor P2 and the n-type transistor N2 of the comparative example were determined. Results showed that the device in the p-type transistor P2 had a mobility of 0.1 cm²/V·s and an ON/OFF ratio of 10⁵ and the device in the n-type transistor N2 had a mobility of 0.01 cm²/V·s and an ON/OFF ratio of 10⁵.

Thus, both the p-type transistor P1 and the n-type transistor N1, which constitute the semiconductor device 1a, exhibited better characteristics than those of the comparative example.

Particularly, the n-type transistor N1 is significantly improved in mobility as compared with the n-type transistor N2. This is because gold used as the electrode material of the electrodes has a low work function, so that the n-type transistor N2, which includes no first layers and no second layers, has a big energy gap between the LUMO of fullerene (C60) and the work function of gold. In contrast, the n-type transistor N1 is significantly improved in carrier injection and extraction because the first layer 17N and the second layer 18N are provided. This allows the n-type transistor N1 to have characteristics substantially equal to those shown in a case where an electrode material with a high work function, such as aluminum, is used.

It is therefore possible to obtain good transistor characteristics in the semiconductor device 1a, even in a case where the electrodes are made from an electrode material that is suitable for characteristics of either an p-type semiconductor layer or an n-type semiconductor layer, that is, even in a case where the source electrode 14 and the drain electrode 15 of the p-type transistor P1 are made from the same electrode material as that of the source electrode 24 and the drain electrode 25 of the n-type transistor N1.

The p-type transistor P1 is also improved in carrier injection and extraction because the first layer 17P and the second layer 18P are provided. Accordingly, the p-type transistor P1 is improved in mobility and ON/OFF ratio as compared with the p-type transistor P2.

Subsequently, a contact resistance in each of the transistors was determined. Results showed that (i) the p-type transistor P1 had a contact resistance that is 1/10 of that of the p-type transistor P2 of the comparative example and (ii) the n-type transistor N1 had a contact resistance that is 1/20 of that of the n-type transistor N2 of the comparative example. Thus, it became possible to reduce the contact resistance by providing the first layer and the second layer.

Note that the contact resistance was evaluated using TLM (Transmission Line Model), which is a known technique disclosed in Nonpatent Literature 1, etc. Specifically, (i) a drain current Id was evaluated in an ON state (Vg=−30 V) while a voltage Vd of −30 V was being applied between source-drain and (ii) an entire resistance Rt (Rt=2Rc+Rch; Rc represents a contact resistance between a source electrode and an organic semiconductor layer and a contact resistance between a drain electrode and the organic semiconductor layer, Rch represents a resistance of a channel part) from the source electrode to the drain electrode was found on the basis of Rt=Vd/Id. Further, Rt was plotted with respect to channel lengths, and Rt, obtained in a case where a channel length is 0 (y-intercept), was taken as the contact resistance.

Subsequently, it was checked whether the semiconductor device 1a functioned as an inverter circuit. FIG. 7 is a view illustrating a configuration of a circuit prepared for an operation check of whether the semiconductor device 1a functioned as an inverter circuit. As illustrated in FIG. 7, Vdd is applied to the source electrode 14 of the p-type transistor P1. A voltage (Output) of the drain electrodes 15 and 25 was measured by use of the circuit illustrated in FIG. 7 when a Vdd of 20 V was applied while a voltage (Input) applied to the gate electrodes 12 and 22 was being swept from 0 V to 20 V. Measurements showed that the semiconductor device 1a certainly exhibited a behavior as an inverter circuit.

As is clear from above evaluations, even in a case where the same material is used as the source electrodes and as the drain electrodes in the semiconductor device 1a that constitutes a complementary logic circuit like a CMOS circuit, the provision of the first layers and the second layers makes it possible to fabricate the p-type transistor and the n-type transistor, each of which has a low contact resistance and excellent characteristics.

### Embodiment 2

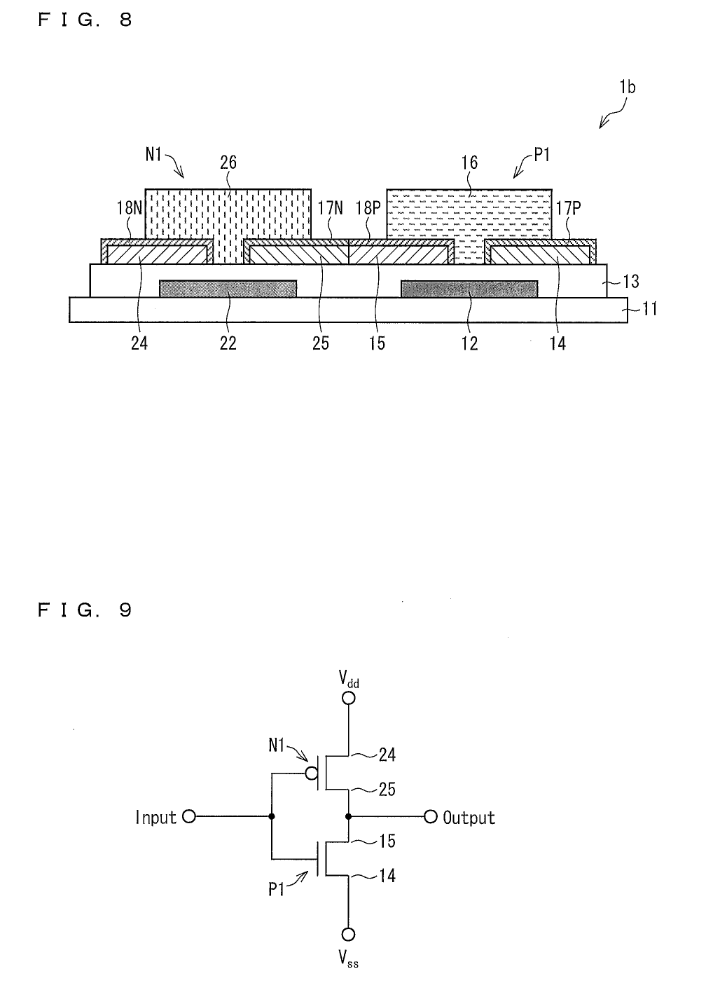

The following description will discuss, with reference to FIGS. 8 through 11, another embodiment of the semiconductor device in accordance with the present invention. For convenience, the same reference signs will be given to members having the respective same functions as those used in Embodiment 1, and descriptions on such members will be omitted.

FIG. 8 is a cross-sectional view illustrating a schematic configuration of a semiconductor device of the present embodiment. As illustrated in FIG. 8, a semiconductor device 1b includes an n-type transistor N1 and a p-type transistor P1 which are provided on a same substrate 11. The semiconductor device 1b is different from the semiconductor device 1a of embodiment 1 in that the positions where the n-type transistor N1 and the p-type transistor P1 are reversed.

The semiconductor device 1b has a configuration in which a drain electrode 15 of the p-type transistor P1 and a drain electrode 25 of the n-type transistor N1 are connected with each other.

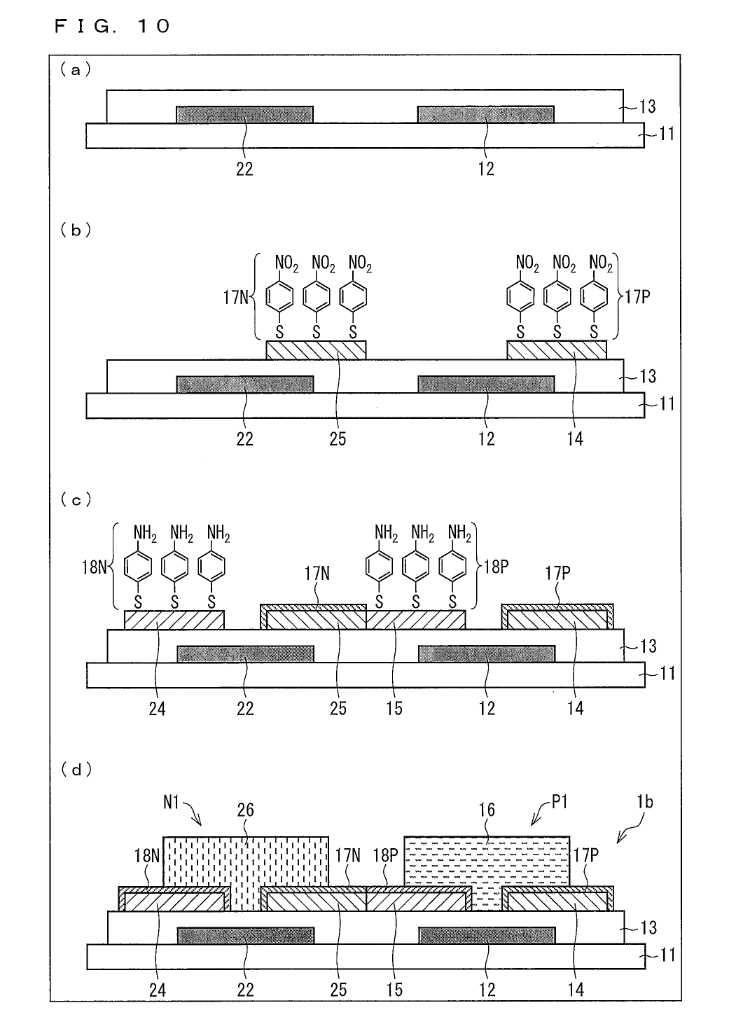

FIG. 9 is an equivalent circuit diagram illustrating a device circuit of the semiconductor device 1b. The semiconductor device 1b has a gate structure in which the p-type transistor P1 and the n-type transistor N1 are connected with each other in a complementary manner. As is clear from FIG. 9, the semiconductor device 1b constitutes an inverter circuit like a CMOS circuit.

As illustrated in FIG. 9, the p-type transistor P1 and the n-type transistor N1 are provided in the semiconductor device 1b so that a source electrode 24 of the n-type transistor N1, the drain electrode 25 of the n-type transistor N1, the drain electrode 15 of the p-type transistor P1, and a source electrode 14 of the p-type transistor P1 are electrically connected in this order between terminals Vdd and Vss. That is, the semiconductor device 1b functions as an inverter circuit in which a negative voltage is applied to the terminal Vdd.

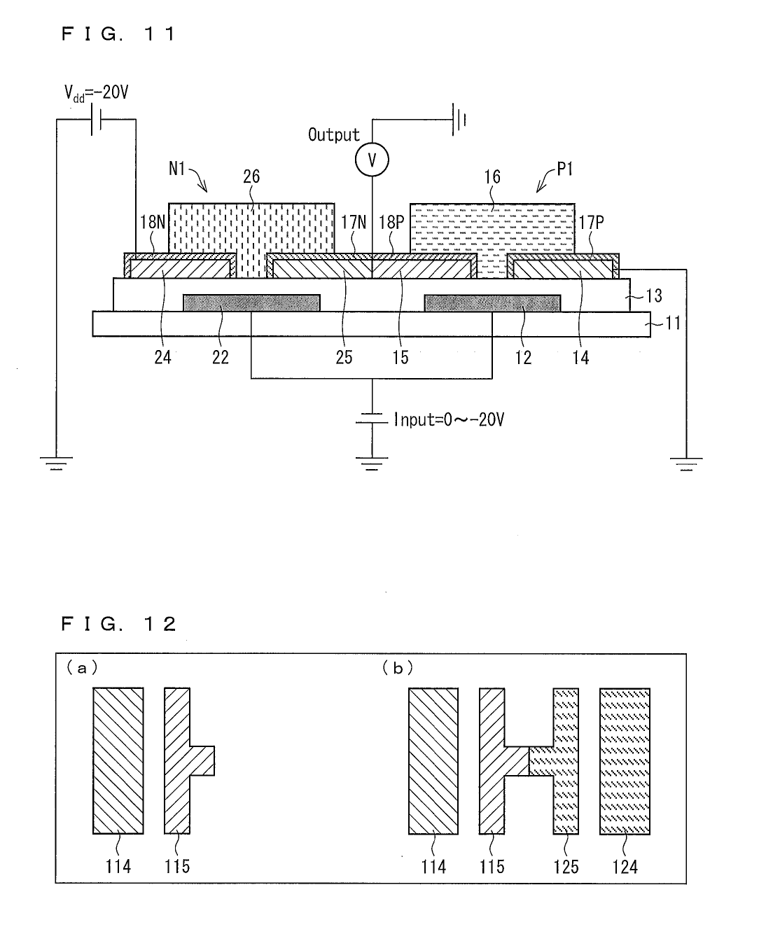

Next, the following description will discuss a method for fabricating the semiconductor device 1b with reference to FIG. 10.

(a) through (d) of FIG. 10 are views schematically illustrating steps in a fabricating process in accordance with the present embodiment.

As illustrated in (a) of FIG. 10, gate electrodes 12 and 22 and a gate insulating film 13 are formed on the substrate 11 by use of the same materials and by the same technique as those employed in the method for fabricating the semiconductor device 1a.

Next, a film of chromium with a film thickness of 5 nm and a film of gold with a film thickness of 60 nm are formed in this order on the gate insulating film 13 by means of vacuum vapor deposition via a metal mask, so that the source electrode 14 of the p-type transistor and the drain electrode 25 of the n-type transistor are formed. Again, chromium plays a role of causing gold and the gate insulating film 13 to adhere to each other.

Note that the source electrode 14 in the semiconductor device 1b is formed in a region corresponding to the region where the source electrode 24 is formed in the semiconductor device 1a. The drain electrode 25 in the semiconductor device 1b is formed at a region corresponding to the region where the drain electrode 15 is formed in the semiconductor device 1a.

After the source electrode 14 and the drain electrode 25 are formed, the substrate is immersed in a 1 mM anhydrous ethanol solution of p-nitrobenzenethiol for 3 hours. This causes first layers 17P and 17N, each made from a SAM of p-nitrobenzenethiol, to be formed on the source electrode 14 and the drain electrode 25, respectively ((b) of FIG. 10). Note that it is preferable that the substrate, which has been immersed for 3 hours, be rinsed with anhydrous ethanol so as to remove p-nitrobenzenethiol excessively adsorbed.

Next, a film of chromium with a film thickness of 5 nm and a film of gold with a film thickness of 60 nm are formed in this order on the gate insulating film 13 by means of vacuum vapor deposition via a metal mask, so that the drain electrode 15 of the p-type transistor and the source electrode 24 of the n-type transistor are formed. Likewise, chromium plays a role of causing gold and the gate insulating film 13 to adhere to each other.

Note that the drain electrode 15 in the semiconductor device 1b is formed at a region corresponding to the region where the drain electrode 25 is formed in the semiconductor device 1a. The source electrode 24 in the semiconductor device 1b is formed at a region corresponding to the region where the source electrode 14 is formed in the semiconductor device 1a.

At this time, the drain electrode 15 is formed so as to be in contact with, that is, electrically connected with, the drain electrode 25 which has been already formed.

Note that, in the present embodiment, the plurality of semiconductor devices, which differ in channel length of their respective transistors, are prepared on the same substrate. That is, the electrodes are formed so that each of the p-type transistor P1 and the n-type transistor N1, which are to be ultimately made, has a channel length of 30 μm, 40 μm, 50 μm, 75 μm, or 100 μm and a channel width of 1000 μm.

After the drain electrode 15 and the source electrode are formed, the substrate is immersed in a 1 mM anhydrous ethanol solution of p-aminobenzenethiol for 3 hours. This causes second layers 18P and 18N, each made from a SAM of p-aminobenzenethiol, to be formed on the drain electrode 15 and the source electrode 24, respectively ((c) of FIG. 10). Note that it is preferable that the substrate, which has been immersed for 3 hours, be rinsed with anhydrous ethanol so as to remove p-aminobenzenethiol excessively adsorbed.

Next, as illustrated in (d) of FIG. 10, a film of fullerene (C60) with a film thickness of 60 nm, which film serves as an n-type semiconductor layer 26, is formed, by vacuum vapor deposition via a metal mask, in an area overlapping the gate electrode 22. The n-type semiconductor layer 26 in the semiconductor device 1b is formed at a region corresponding to the region where the p-type semiconductor layer 16 is formed in the semiconductor device 1a. Thus, the n-type transistor N1 of the semiconductor device 1b is formed.

Subsequently, a film of pentacene with a film thickness of 60 nm, which film serves as a p-type semiconductor layer 16, is formed, by vacuum vapor deposition via a metal mask, in an area overlapping the gate electrode 12. The p-type semiconductor layer 16 in the semiconductor device 1b is formed at a region corresponding to the region where the n-type semiconductor layer 26 is formed in the semiconductor device 1a. Thus, the p-type transistor P1 of the semiconductor device 1b is formed.

In this way, it is possible to fabricate the semiconductor device 1b that constitutes a complementary logic circuit in which the p-type transistor P1 and the n-type transistor N1 are connected with each other in a complementary manner.

Next, (i) characteristics of the semiconductor device 1b thus fabricated and (i) characteristics of the p-type transistor P1 and the n-type transistor N1 which constitute the semiconductor device 1b were determined.

Results showed that transistor characteristics (mobility, ON/OFF ratio, and contact resistance) in the p-type transistor P1 by itself and transistor characteristics in the n-type transistor N1 by itself were good and substantially equal to those in the semiconductor device 1a.

Subsequently, it was checked whether the semiconductor device 1b functioned as an inverter circuit. FIG. 11 is a view illustrating a configuration of a circuit prepared for an operation check of whether the semiconductor device 1b functioned as an inverter circuit. As illustrated in FIG. 11, Vdd is applied to the source electrode 24 of the n-type transistor N1. A voltage (Output) of the drain electrodes 15 and 25 was measured by use of the circuit illustrated in FIG. 11 when a Vdd of −20 V was applied while a voltage (Input) applied to the gate electrodes 12 and 22 was being swept from 0 V to −20 V. Measurements showed that the semiconductor device 1b certainly exhibited a behavior as an inverter circuit.

As is clear from above evaluations, even in a case where the same material is used as the source electrodes and as the drain electrodes in the semiconductor device 1b that constitutes a complementary logic circuit like a CMOS circuit, the provision of the first layers and the second layers makes it possible to fabricate the p-type transistor and the n-type transistor, each of which has a low contact resistance and excellent characteristics.

### Embodiment 3

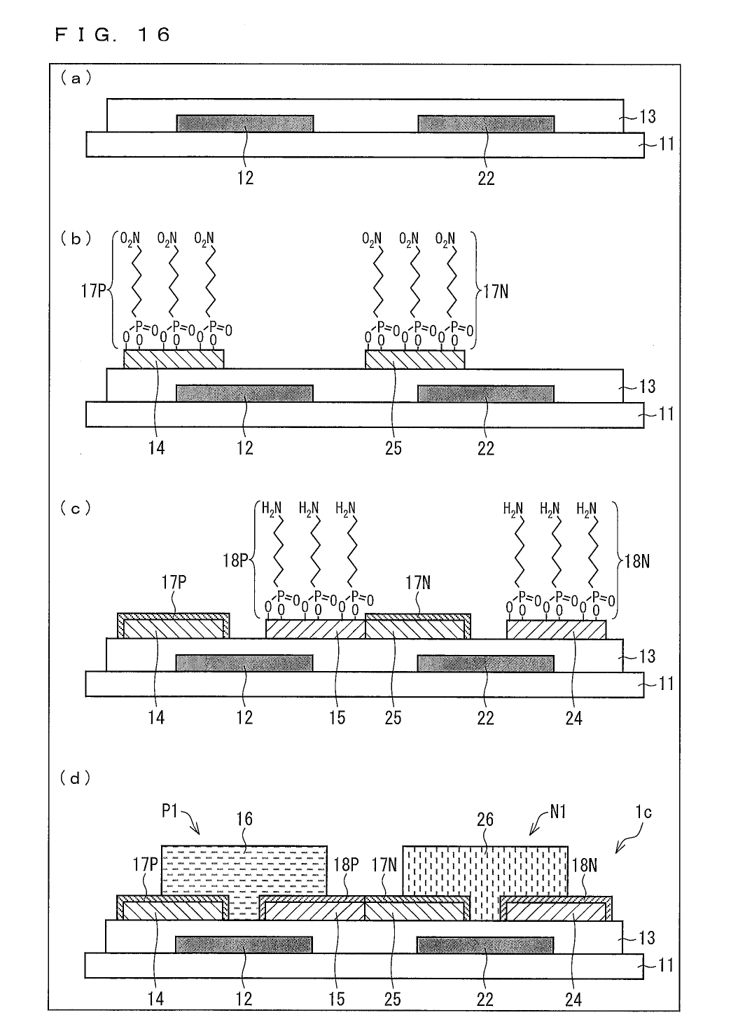

The following description will discuss, with reference to FIGS. 15 and 16, still another embodiment of the semiconductor device in accordance with the present invention. For convenience, the same reference signs will be given to members having the respective same functions as those used in Embodiments 1 and 2, and descriptions on such members will be omitted.

(a) of FIG. 15 is a cross-sectional view illustrating a schematic configuration of a semiconductor device of the present embodiment. Like the semiconductor device 1a illustrated in FIG. 1, a semiconductor device 1c includes an n-type transistor N1 and a p-type transistor P1 which are provided on a same substrate 11. The semiconductor device 1c has a configuration different from that of the semiconductor device 1a in that self-assembled monolayers constituting respective first layers 17P and 17N and self-assembled monolayers constituting respective second layers 18P and 18N in the semiconductor device 1c are each constituted by molecules each having linear alkane as a main chain backbone. A molecule in each of the self-assembled monolayers constituting the respective first layers 17P and 17N is shown in (b) of FIG. 15. A molecule in each of the self-assembled monolayers constituting the respective second layers 18P and 18N is shown in (c) of FIG. 15. Note that each of (b) and (c) of FIG. 15 shows only one (1) molecule for easy explanation and illustrates a state after formation of the self-assembled monolayer and before formation of the semiconductor layer.

The semiconductor device 1c has a device circuit that is identical with the device circuit illustrated in FIG. 2.

Next, the following description will discuss a method for fabricating the semiconductor device 1c with reference to FIG. 16.

(a) through (d) of FIG. 16 are views schematically illustrating steps in a fabricating process in accordance with the present embodiment.

As illustrated in (a) of FIG. 16, gate electrodes 12 and 22 and a gate insulating film 13 are formed on the substrate 11 by use of the same materials and by the same technique as those employed in the method for fabricating the semiconductor device 1a.

Next, a film of ITO (Indium Tin Oxide) with a film thickness of 60 nm is formed on the gate insulating film 13 by sputtering via a metal mask, so that a source electrode 14 of the p-type transistor and a drain electrode 25 of the n-type transistor are formed.

After the source electrode 14 and the drain electrode are formed, the substrate is immersed in a 1 mM anhydrous acetonitrile solution of 6-nitrohexane-1-phosphonic acid for 3 hours. This causes the first layers 17P and 17N, each made from a SAM of 6-nitrohexane-1-phosphonic acid, to be formed on the source electrode 14 and the drain electrode 25, respectively ((b) of FIG. 16). Note that it is preferable that the substrate, which has been immersed for 3 hours, be rinsed with acetonitrile so as to remove 6-nitrohexane-1-phosphonic acid excessively adsorbed.

Next, a film of ITO with a film thickness of 60 nm is formed on the gate insulating film 13 by sputtering via a metal mask, so that a drain electrode 15 of the p-type transistor and a source electrode 24 of the n-type transistor are formed.

At this time, the drain electrode 15 is formed so as to be in contact with, that is, electrically connected with the drain electrode 25 which has been already formed.

Note that, in the present embodiment, the plurality of semiconductor devices, which differ in channel length of their respective transistors, are prepared on the same substrate. That is, the electrodes are formed so that each of the p-type transistor P1 and the n-type transistor N1, which are to be ultimately made, has a channel length of 30 μm, 40 μm, 50 μm, 75 μm, or 100 μm and a channel width of 1000 μm.

After the drain electrode 15 and the source electrode 24 are formed, the substrate is immersed in a 1 mM anhydrous acetonitrile solution of 6-aminohexane-1-phosphonic acid for 3 hours. This causes the second layers 18P and 18N, each made from a SAM of 6-aminohexane-1-phosphonic acid, to be formed on the drain electrode 15 and the source electrode 24, respectively ((c) of FIG. 16). Note that it is preferable that the substrate, which has been immersed for 3 hours, be rinsed with anhydrous acetonitrile so as to remove 6-aminohexane-1-phosphonic acid excessively adsorbed.

Subsequently, as illustrated in (d) of FIG. 16, (i) a film of pentacene with a film thickness of 60 nm, which film serves as a p-type semiconductor layer 26 and (ii) a film of fullerene (C60) with a film thickness of 60 nm, which film serves as an n-type semiconductor layer 16, are formed one by one by vacuum vapor deposition via a metal mask.

In this way, it is possible to fabricate the semiconductor device 1c that constitutes a complementary logic circuit in which the p-type transistor P1 and the n-type transistor N1 are connected with each other in a complementary manner.

Next, (i) characteristics of the semiconductor device 1c and (i) characteristics of the p-type transistor P1 and the n-type transistor N1 which constitute the semiconductor device 1c were determined by the same technique as that used in the case of the semiconductor device 1a.

Results showed that transistor characteristics (mobility, ON/OFF ratio, and contact resistance) in the p-type transistor P1 by itself and transistor characteristics in the n-type transistor N1 by itself were good and substantially equal to those in the semiconductor device 1a.

Subsequently, it was checked whether the semiconductor device 1b functioned as an inverter circuit. Evaluation was carried out using the same technique as that used in the case as illustrated in FIG. 7. The evaluation showed that the semiconductor device 1b certainly exhibited a behavior as an inverter circuit.

As is clear from above evaluations, even in a case where the same material is used as the source electrodes and as the drain electrodes in the semiconductor device 1b that constitutes a complementary logic circuit like a CMOS circuit, the provision of the first layers and the second layers makes it possible to fabricate the p-type transistor and the n-type transistor, each of which has a low contact resistance and excellent characteristics.

The present invention is not limited to the above-described embodiments but allows various modifications within the scope of the claims. That is, any embodiment derived from a combination of technical means appropriately modified within the scope of the claims will also be included in the technical scope of the present invention.

In the semiconductor device in accordance with the present invention, the first layer in the p-type organic transistor and the first layer in the n-type organic transistor be preferably made from the same material and the second layer in the p-type organic transistor and the second layer in the n-type organic transistor be preferably made from the same material.

According to the configuration, it is only necessary to prepare two materials, one of which is suitable for the first layers and the other of which is suitable for the second layers. This makes it possible to reduce a fabrication cost of the semiconductor device.

In the semiconductor device in accordance with the present invention, each of the first layer in the p-type organic transistor, the first layer in the n-type organic transistor, the second layer in the p-type organic transistor, and the second layer in the n-type organic transistor is preferably a self-assembled monolayer constituted by molecules each having an electric dipole moment.

According to the configuration, molecules each having an electric dipole moment are present at an interface between each electrode and the organic semiconductor layer, so that an electric charge injection efficiency or an electric charge extraction efficiency can be improved in the interface between the electrode and the organic semiconductor layer. This improves a mobility in each of the p-type organic semiconductor and the n-type organic semiconductor, which constitute the semiconductor device. It thus becomes possible to provide a semiconductor device having excellent characteristics.

In the semiconductor device in accordance with the present invention, each of the electric dipole moments in the first layer between the first source electrode and the p-type organic semiconductor layer preferably points in a direction from the p-type organic semiconductor layer toward the first source electrode, each of the electric dipole moments in the first layer between the second drain electrode and the n-type organic semiconductor layer preferably points in a direction from the n-type organic semiconductor layer toward the second drain electrode, each of the electric dipole moments in the second layer between the first drain electrode and the p-type organic semiconductor layer preferably points in a direction from the first drain electrode toward the p-type organic semiconductor layer, and each of the electric dipole moments in the second layer between the second source electrode and the n-type organic semiconductor layer preferably points in a direction from the second source electrode toward the n-type organic semiconductor layer.

The configuration makes it possible to enhance (i) injection of electric charge at the first layer provided on the first source electrode and at the second layer provided on the second source electrode and (ii) extraction of electric charge at the second layer provided on the first drain electrode and at the first layer provided on the second drain electrode. This improves a mobility in each of the p-type organic semiconductor and the n-type organic semiconductor, which constitute the semiconductor device. It thus becomes possible to provide a semiconductor device having excellent characteristics.

In the semiconductor device in accordance with the present invention, each of the molecules in each of the first layers is preferably a compound expressed by General Formula (1):

X-A-Y¹ (1)

where X is a functional group, the functional group and an atom constituting the first source electrode form a chemical bond, the functional group and an atom constituting the second drain electrode form a chemical bond, A is a π-conjugated moiety or an aliphatic moiety, and Y¹ is an electron withdrawing group.

Likewise, according to the semiconductor device in accordance with the present invention, each of the molecules in each of the second layers is preferably a compound expressed by General Formula (2):

X-A-Y² (2)

where X is a functional group, the functional group and an atom constituting the first drain electrode form a chemical bond, the functional group and an atom constituting the second source electrode form a chemical bond, A is a π-conjugated moiety or an aliphatic moiety, and Y¹ is an electron donating group).

According to the configuration, each of the molecules constituting the first layers and the second layers has a π electron. This causes a reduction in the resistance of each of the first layers themselves and a reduction in the resistance of each of the second layers themselves. In addition, each of the molecules constituting the first layers and the second layers can firmly bind to corresponding one of the electrode materials at a functional group X of the molecule. This makes it possible to attain a longer lifespan of the semiconductor device.

Further, since Y¹ is an electron withdrawing group, a negatively charged state is created in the vicinity of Y¹. This allows an electric dipole moment to be formed in each of the first layers, which electric dipole moment points in a direction from corresponding one of the organic semiconductor layers to corresponding one of the electrodes. Since Y² is an electron donating group, a positively charged state is created in the vicinity of Y². This allows an electric dipole moment to be formed in each of the second layers, which electric dipole moment points in a direction from corresponding one of the electrodes to corresponding one of the organic semiconductor layers.

Note that the silane coupling group is a functional group represented by —SiR¹₃ (wherein (i) at least one of the three R¹ is a chloro group, a methoxy group, or an ethoxy group, each of which is involved in the binding and (ii) each of the other(s) of the three R¹ is hydrogen or a methyl group, each of which is uninvolved in the binding). The phosphonate moiety is a functional moiety represented by —POR²₂ (wherein at least one of the two R² is a chloro group or a hydroxy group, each of which is involved in the binding and the other is a methyl group or a methoxy group, each of which is uninvolved in the binding).

In the semiconductor device in accordance with the present invention, the first drain electrode is preferably connected with the second drain electrode so as to constitute a complementary logic circuit.

With the configuration, it is possible to provide, by use of an organic semiconductor, a semiconductor device which has (i) a same function similar to that of a CMOS (Complementary Metal Oxide Semiconductor) inverter circuit and (ii) an excellent mobility characteristic.

In a method for fabricating a semiconductor device in accordance with the present invention, the first source electrode, the first drain electrode, the second source electrode, and the second drain electrode are preferably made from a same electrode material.

With the configuration, the source electrode or the drain electrode in the p-type organic transistor can be formed and patterned simultaneously with the source electrode or the drain electrode in the n-type organic transistor. This makes it possible to reduce the number of steps in the fabrication process of the semiconductor device.

By using the same material for fabricating all of the source electrodes and the drain electrodes, it becomes possible to reduce the fabrication cost.

According to the method for fabricating the semiconductor device in accordance with the present invention, each of the first layer in the p-type organic transistor, the first layer in the n-type organic transistor, the second layer in the p-type organic transistor, and the second layer in the n-type organic transistor is preferably formed by forming a self-assembled monolayer by use of molecules each having an electric dipole moment.

With the configuration, the molecules each having an electric dipole moment constitute the self-assembled monolayer (i.e., the molecules are arranged in a self-organized manner). This makes it possible to control easily the direction of the electric dipole moment in each of the first layers and the second layers.

Further, since a film thickness of each of the first layers and the second layers can be reduced to a molecular length of the molecules constituting corresponding one of the self-assembled monolayers, it is possible to reduce the resistance of each of the first layers themselves and the resistance of each of the second layers themselves. This makes it possible to improve the characteristics of the semiconductor device which is fabricated.

### INDUSTRIAL APPLICABILITY

The present invention is applicable to any electronic device employing a CMOS circuit. The present invention can be particularly suitably applied to a flexible display, an electronic tag, and the like in which the characteristics of an organic transistor is utilized.

### REFERENCE SIGNS LIST

1a, 1b, and 1c: semiconductor device
11: substrate
12: gate electrode (first gate electrode)
13: gate insulating film
14: source electrode (first source electrode)
15: drain electrode (first drain electrode)
16: p-type organic semiconductor layer
17P and 17N: first layer
18P and 18N: second layer
22: gate electrode (second gate electrode)
24: source electrode (second source electrode)
25: drain electrode (second drain electrode)
26: n-type organic semiconductor layer
N1: n-type organic transistor
P1: p-type organic transistor

1. A semiconductor device comprising:
a p-type organic transistor having a first gate electrode, a first source electrode, a first drain electrode, and a p-type organic semiconductor layer;
an n-type organic transistor electrically connected with the p-type organic transistor and having a second gate electrode, a second source electrode, a second drain electrode, and an n-type organic semiconductor layer;
first layers for enhancing electric charge transfer, one of the first layers being provided between the first source electrode and the p-type organic semiconductor layer, the other of the first layers being provided between the second drain electrode and the n-type organic semiconductor; and
second layers which are (i) for enhancing electric charge transfer and (ii) made from a different material from that of the first layers, one of the second layers being provided between the first drain electrode and the p-type organic semiconductor layer, the other of the second layers being provided between the second source electrode and the n-type organic semiconductor layer,
the first source electrode, the first drain electrode, the second source electrode, and the second drain electrode being made from a same electrode material.

2. The semiconductor device as set forth in claim 1, wherein:
the first layer in the p-type organic transistor and the first layer in the n-type organic transistor are made from the same material and
the second layer in the p-type organic transistor and the second layer in the n-type organic transistor are made from the same material.

3. The semiconductor device as set forth in claim 1, wherein each of the first layer in the p-type organic transistor, the first layer in the n-type organic transistor, the second layer in the p-type organic transistor, and the second layer in the n-type organic transistor is a self-assembled monolayer constituted by molecules each having an electric dipole moment.

4. The semiconductor device as set forth in claim 3, wherein:
each of the electric dipole moments in the first layer between the first source electrode and the p-type organic semiconductor layer points in a direction from the p-type organic semiconductor layer toward the first source electrode,
each of the electric dipole moments in the first layer between the second drain electrode and the n-type organic semiconductor layer points in a direction from the n-type organic semiconductor layer toward the second drain electrode,
each of the electric dipole moments in the second layer between the first drain electrode and the p-type organic semiconductor layer points in a direction from the first drain electrode toward the p-type organic semiconductor layer, and
each of the electric dipole moments in the second layer between the second source electrode and the n-type organic semiconductor layer points in a direction from the second source electrode toward the n-type organic semiconductor layer.

5. The semiconductor device as set forth in claim 3, wherein each of the molecules in each of the first layers is a compound expressed by General Formula (1):
X-A-Y¹ (1)
where X is a functional group, the functional group and an atom constituting the first source electrode form a chemical bond, the functional group and an atom constituting the second drain electrode form a chemical bond, A is π-conjugated moiety or an aliphatic moiety, and Y¹ is an electron withdrawing group.

6. The semiconductor device as set forth in claim 3, wherein each of the molecules in each of the second layers is a compound expressed by General Formula (2):
X-A-Y² (2)
where X is a functional group, the functional group and an atom constituting the first drain electrode form a chemical bond, the functional group and an atom constituting the second source electrode form a chemical bond, A is π-conjugated moiety or an aliphatic moiety, and Y¹ is an electron donating group.

7. The semiconductor device as set forth in claim 1, wherein the first drain electrode is connected with the second drain electrode so as to constitute a complementary logic circuit.

8. A method for fabricating a semiconductor device,
said semiconductor device including:
a p-type organic transistor having a first gate electrode, a first source electrode, a first drain electrode, and a p-type organic semiconductor layer; and
an n-type organic transistor coupled with the p-type organic transistor and having a second gate electrode, a second source electrode, a second drain electrode, and an n-type organic semiconductor layer,
said method comprising the steps of:
(a) forming first layers, one each on the first source electrode and the second drain electrode, after formation of the first source electrode and the second drain electrode and before formation of the p-type organic semiconductor layer and the n-type organic semiconductor layer, the first layers enhancing electric charge transfer; and
(b) forming second layers, one each on the first drain electrode and the second source electrode, after formation of the first drain electrode and the second source electrode and before formation of the p-type organic semiconductor layer and the n-type organic semiconductor layer, the second layers enhancing electric charge transfer and being made from a different material from that of the first layers.

9. The method for fabricating the semiconductor device as set forth in claim 8, wherein the first source electrode, the first drain electrode, the second source electrode, and the second drain electrode are made from a same electrode material.

10. The method for fabricating the semiconductor device as set forth in claim 8, wherein each of the first layer in the p-type organic transistor, the first layer in the n-type organic transistor, the second layer in the p-type organic transistor, and the second layer in the n-type organic transistor is formed by forming a self-assembled monolayer by use of molecules each having an electric dipole moment.
